(19) United States
(12) Patent Application Publication
(10) Pub. No.: US 2024/0162165 A1
(43) Pub. Date: May 16, 2024

(54) NITRIDE SEMICONDUCTOR DEVICE AND METHOD FOR MANUFACTURING THE SAME

(71) Applicant: ROHM CO., LTD., Kyoto-shi (JP)

(72) Inventor: Keita SHIKATA, Kyoto-shi (JP)

(73) Assignee: ROHM CO., LTD., Kyoto-shi (JP)

(21) Appl. No.: 18/416,935

(22) Filed: Jan. 19, 2024

Related U.S. Application Data
(63) Continuation of application No. PCT/JP2022/025461, filed on Jun. 27, 2022.

(30) Foreign Application Priority Data
Jul. 26, 2021 (JP) 2021-121612

(51) Int. Cl. H01L 23/00; H01L 21/02; H01L 23/482; H01L 29/20; H01L 29/417; H01L 29/66; H01L 29/778

(52) U.S. Cl. CPC H01L 23/562; H01L 21/02378; H01L 21/0254; H01L 23/4824; H01L 29/2003; H01L 29/41766; H01L 29/66462; H01L 29/7786

(57) ABSTRACT

A nitride semiconductor device 1 includes a conductive SiC substrate 2 that has a first surface 2a and a second surface 2b opposite thereto, a semi-insulating SiC layer 3 that is formed in at least a portion of a surface layer portion at the first surface 2a side of the conductive SiC substrate 2, and a nitride epitaxial layer 40 that is formed on the conductive SiC substrate 2 such as to cover the semi-insulating SiC layer 3.

### CROSS-REFERENCE TO RELATED APPLICATIONS

The present application is a continuation application of PCT Application No. PCT/JP2022/025461, filed on Jun. 27, 2022, which corresponds to Japanese Patent Application No. 2021-121612 filed on Jul. 26, 2021 with the Japan Patent Office, and the entire disclosure of these applications is incorporated herein by reference.

### TECHNICAL FIELD

The present disclosure relates to a nitride semiconductor device that is constituted of a group III nitride semiconductor (hereinafter referred to at times simply as “nitride semiconductor”) and a method for manufacturing the same.

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples. It can generally be expressed as AlₓIn_{y}Ga_{1-x-y}N (0≤x≤1, 0≤y≤1, 0≤x+y≤1).

Generally, in a nitride semiconductor device used in a high frequency application, an SiC (Silicon Carbide) substrate that is semi-insulating is used as a semiconductor substrate to reduce a parasitic capacitance (see, for example, Japanese Patent Application Publication No. 2019-110256).

### BRIEF DESCRIPTION OF DRAWINGS

FIG. 1 is an illustrative plan view for describing the arrangement of a nitride semiconductor device according to a first preferred embodiment of the present disclosure.

FIG. 2 is an enlarged plan view of a principal portion of FIG. 1.

FIG. 3 is an illustrative enlarged sectional view taken along line III-III of FIG. 1.

FIG. 4 is an illustrative enlarged sectional view taken along line IV-IV of FIG. 2.

FIG. 5A is a sectional view showing an example of a manufacturing process of the nitride semiconductor device.

FIG. 5B is a sectional view showing a step subsequent to that of FIG. 5A.

FIG. 5C is a sectional view showing a step subsequent to that of FIG. 5B.

FIG. 5D is a sectional view showing a step subsequent to that of FIG. 5C.

FIG. 5E is a sectional view showing a step subsequent to that of FIG. 5D.

FIG. 5F is a sectional view showing a step subsequent to that of FIG. 5E.

FIG. 5G is a sectional view showing a step subsequent to that of FIG. 5F.

FIG. 5H is a sectional view showing a step subsequent to that of FIG. 5G.

FIG. 5I is a sectional view showing a step subsequent to that of FIG. 5H.

FIG. 5J is a sectional view showing a step subsequent to that of FIG. 5I.

FIG. 5K is a sectional view showing a step subsequent to that of FIG. 5J.

FIG. 5L is a sectional view showing a step subsequent to that of FIG. 5K.

FIG. 6A is a sectional view showing an example of a manufacturing process of the nitride semiconductor device.

FIG. 6B is a sectional view showing a step subsequent to that of FIG. 6A.

FIG. 6C is a sectional view showing a step subsequent to that of FIG. 6B.

FIG. 6D is a sectional view showing a step subsequent to that of FIG. 6C.

FIG. 6E is a sectional view showing a step subsequent to that of FIG. 6D.

FIG. 6F is a sectional view showing a step subsequent to that of FIG. 6E.

FIG. 6G is a sectional view showing a step subsequent to that of FIG. 6F.

FIG. 6H is a sectional view showing a step subsequent to that of FIG. 6G.

FIG. 6I is a sectional view showing a step subsequent to that of FIG. 6H.

FIG. 6J is a sectional view showing a step subsequent to that of FIG. 6I.

FIG. 6K is a sectional view showing a step subsequent to that of FIG. 6J.

FIG. 6L is a sectional view showing a step subsequent to that of FIG. 6K.

FIG. 7 is an illustrative plan view for describing the arrangement of a nitride semiconductor device according to a second preferred embodiment of the present disclosure.

FIG. 8 is an illustrative enlarged sectional view taken along line VIII-VIII of FIG. 7.

FIG. 9 is an illustrative enlarged sectional view taken along line IX-IX of FIG. 7.

FIG. 10A is a sectional view showing an example of a manufacturing process of the nitride semiconductor device.

FIG. 10B is a sectional view showing a step subsequent to that of FIG. 10A.

FIG. 10C is a sectional view showing a step subsequent to that of FIG. 10B.

FIG. 10D is a sectional view showing a step subsequent to that of FIG. 10C.

FIG. 10E is a sectional view showing a step subsequent to that of FIG. 10D.

FIG. 10F is a sectional view showing a step subsequent to that of FIG. 10E.

FIG. 10G is a sectional view showing a step subsequent to that of FIG. 10F.

FIG. 10H is a sectional view showing a step subsequent to that of FIG. 10G.

FIG. 10I is a sectional view showing a step subsequent to that of FIG. 10H.

FIG. 10J is a sectional view showing a step subsequent to that of FIG. 10I.

FIG. 10K is a sectional view showing a step subsequent to that of FIG. 10J.

### DESCRIPTION OF EMBODIMENTS

A preferred embodiment of the present disclosure provides a nitride semiconductor device including a conductive SiC substrate that has a first surface and a second surface opposite thereto, a semi-insulating SiC layer that is formed in at least a portion of a surface layer portion at the first surface side of the conductive SiC substrate, and a nitride epitaxial layer that is formed on the conductive SiC substrate such as to cover the semi-insulating SiC layer.

With this arrangement, the nitride semiconductor device that uses the conductive SiC substrate as a semiconductor substrate and is a nitride semiconductor device that enables suppression of warping of the conductive SiC substrate and internal cracking of the nitride epitaxial layer and reduction of parasitic capacitance can be obtained.

In the preferred embodiment of the present disclosure, the nitride epitaxial layer on the semi-insulating SiC layer is formed on a silicon plane of the semi-insulating SiC layer.

In the preferred embodiment of the present disclosure, a film thickness of the nitride epitaxial layer is not more than 4 μm (micro meter).

In the preferred embodiment of the present disclosure, a film thickness of the nitride epitaxial layer is not more than 2.5 μm.

In the preferred embodiment of the present disclosure, a source electrode, a drain electrode, and a gate electrode that are disposed on the nitride epitaxial layer, an insulating film that is formed on the nitride epitaxial layer such as to cover the source electrode, the drain electrode, and the gate electrode, a gate pad that is formed on the insulating film and is electrically connected to the gate electrode, and a drain pad that is formed on the insulating film and is electrically connected to the drain electrode are included.

In the preferred embodiment of the present disclosure, the semi-insulating SiC layer includes a first semi-insulating SiC layer that is formed inside a region below the drain pad in plan view.

In the preferred embodiment of the present disclosure, the semi-insulating SiC layer includes a second semi-insulating SiC layer that is formed inside a region below the gate pad in plan view.

In the preferred embodiment of the present disclosure, the semi-insulating SiC layer includes a first semi-insulating SiC layer that is formed inside a region below the drain pad in plan view and a second semi-insulating SiC layer that is formed inside a region below the gate pad in plan view.

In the preferred embodiment of the present disclosure, the nitride semiconductor device has, in plan view, an active region in which a two-dimensional electron gas can form inside the nitride epitaxial layer and an inactive region in which a two-dimensional electron gas is not formed inside the nitride epitaxial layer, the drain pad has a first drain pad region that is disposed inside the inactive region in plan view, and the first semi-insulating SiC layer includes a portion that is disposed inside a region below the first drain pad region.

In the preferred embodiment of the present disclosure, the nitride semiconductor device has, in plan view, an active region in which a two-dimensional electron gas can form inside the nitride epitaxial layer and an inactive region in which a two-dimensional electron gas is not formed inside the nitride epitaxial layer, the gate pad has a first gate pad region that is disposed inside the inactive region in plan view, and the second semi-insulating SiC layer includes a portion that is disposed inside a region below the first gate pad region.

In the preferred embodiment of the present disclosure, a conductive member that penetrates through the nitride epitaxial layer and electrically connects the source electrode and the conductive SiC substrate is included.

In the preferred embodiment of the present disclosure, the nitride epitaxial layer includes a first nitride semiconductor layer that constitutes an electron transit layer and a second nitride semiconductor layer that is formed on the first nitride semiconductor layer, constitutes an electron supply layer, and is higher in bandgap than the first nitride semiconductor layer.

In the preferred embodiment of the present disclosure, a semi-insulating nitride layer that is disposed between the conductive SiC substrate and the first nitride semiconductor layer and with which an acceptor concentration is higher than a donor concentration is included.

In the preferred embodiment of the present disclosure, a buffer layer that is disposed between the conductive SiC substrate and the semi-insulating nitride layer and is constituted of a nitride semiconductor is included.

In the preferred embodiment of the present disclosure, the first nitride semiconductor layer is constituted of a GaN layer and the second nitride semiconductor layer is constituted of an AlGaN layer.

In the preferred embodiment of the present disclosure, the first nitride semiconductor layer is constituted of a GaN layer, the second nitride semiconductor layer is constituted of an AlGaN layer, and the semi-insulating nitride layer is constituted of a GaN layer that contains carbon.

In the preferred embodiment of the present disclosure, the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of a laminated film of an AlN layer that is formed on the first surface and an AlGaN layer that is laminated on the AlN layer, an AlN layer, or an AlGaN layer.

In the preferred embodiment of the present disclosure, a resistivity of the semi-insulating SiC layer is not less than 1×10³Ω·cm.

A preferred embodiment of the present disclosure provides a method for manufacturing a nitride semiconductor device including a step of forming a semi-insulating SiC layer in at least a portion of a surface layer portion at a first surface side of a conductive SiC substrate that has the first surface and a second surface opposite thereto and a step of forming a nitride epitaxial layer on the conductive SiC substrate such as to cover the semi-insulating SiC layer.

With the present manufacturing method, the nitride semiconductor device that uses the conductive SiC substrate as a semiconductor substrate and is a nitride semiconductor device that enables suppression of warping of the conductive SiC substrate and internal cracking of the nitride epitaxial layer and reduction of parasitic capacitance can be manufactured.

In the following, preferred embodiments of the present disclosure shall be described in detail with reference to the attached drawings.

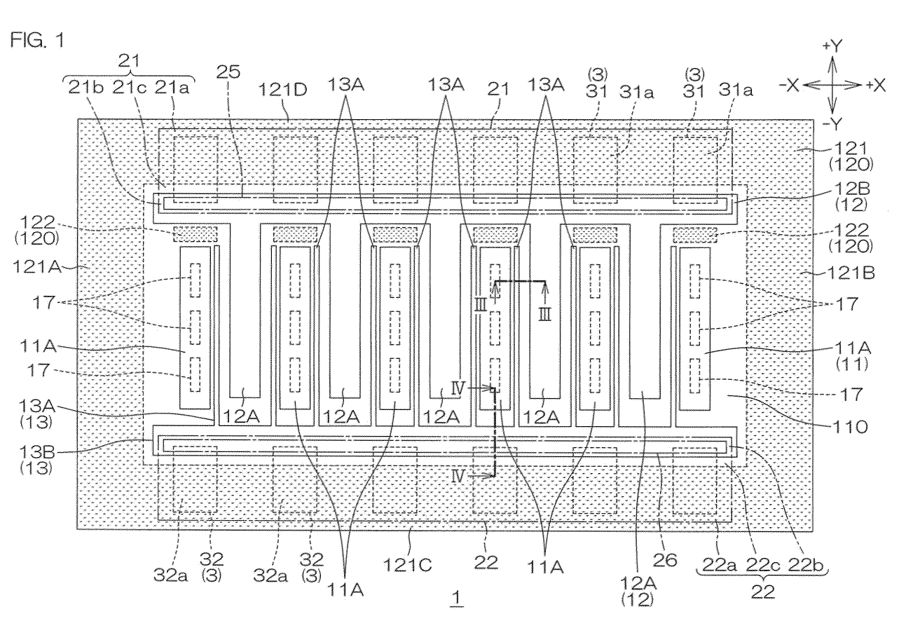

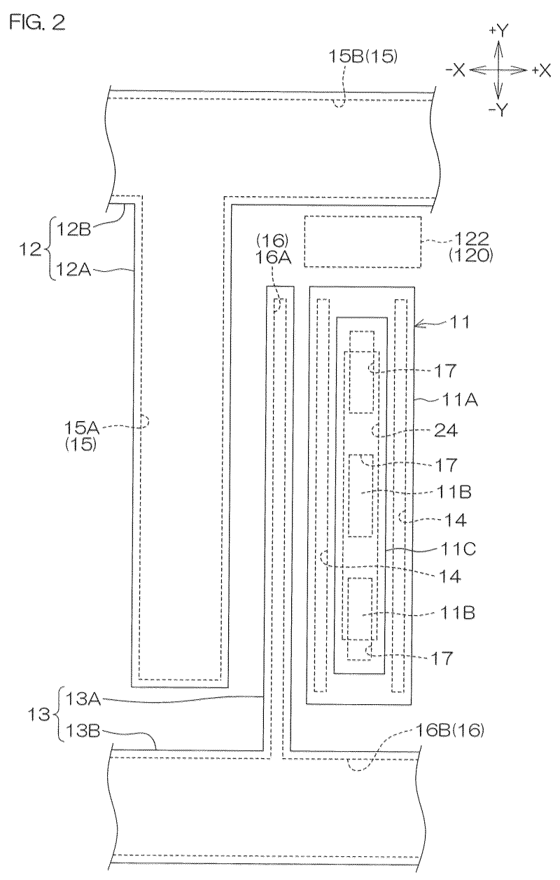

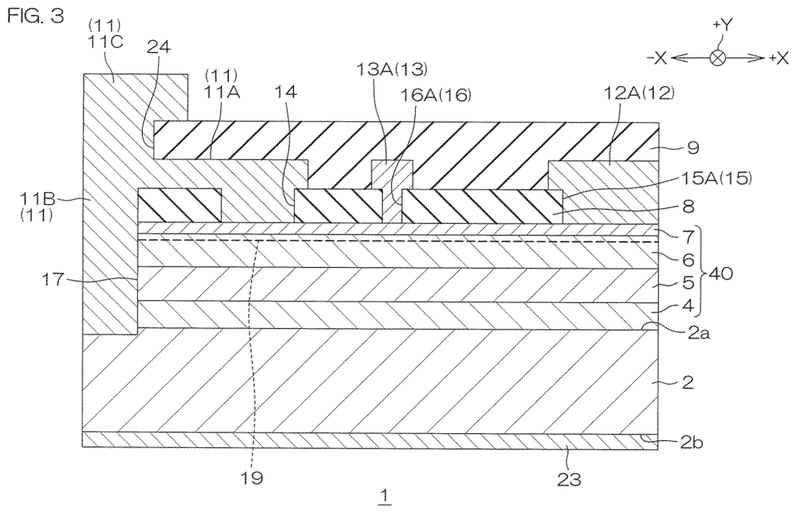

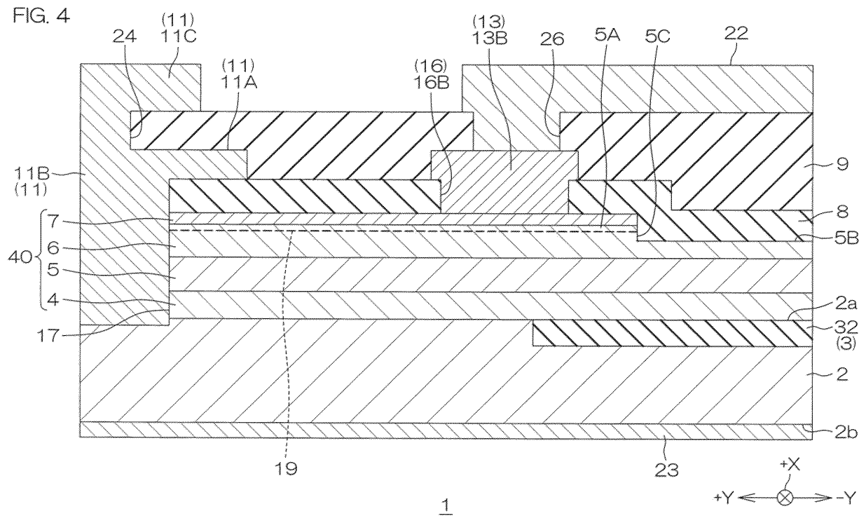

FIG. 1 is an illustrative plan view for describing the arrangement of a nitride semiconductor device according to a first preferred embodiment of the present disclosure. FIG. 2 is an enlarged plan view of a principal portion of FIG. 1. FIG. 3 is an illustrative enlarged sectional view taken along line III-III of FIG. 1. FIG. 4 is an illustrative enlarged sectional view taken along line IV-IV of FIG. 2.

However, in FIG. 1, an interlayer insulating film 9 (see FIG. 3 and FIG. 4), extension portions 11C (see FIG. 3 and FIG. 4) of source electrodes 11 that are formed on the interlayer insulating film 9, and source via holes 24 (see FIG. 4), a drain via hole 25, a gate via hole 26 (see FIG. 4), a drain pad 21, and a gate pad 22 (see FIG. 4) that are formed in or on the interlayer insulating film 9 are omitted for convenience of description. However, in FIG. 1, the drain via hole 25, the gate via hole 26, the drain pad 21, and the gate pad 22 are indicated by alternate long and two short dashed lines. In addition, in FIG. 2, the extension portion 11C of the source electrode 11 is indicated by solid lines and the source via hole 24 is indicated by broken lines for clarity.

For convenience of description, a +X direction, a −X direction, a +Y direction, and a −Y direction shown in FIG. 1 are used at times in the following description. The +X direction is a predetermined direction along a front surface of a conductive SiC substrate 2 in plan view and the +Y direction is a direction along the front surface of the conductive SiC substrate 2 in plan view and is a direction that is orthogonal to the +X direction.

The −X direction is a direction opposite to the +X direction. The −Y direction is a direction opposite to the +Y direction. The +X direction and the −X direction shall be referred to simply as the “X direction” when referred to collectively, and the +Y direction and the −Y direction shall be referred to simply as the “Y direction” when referred to collectively.

A nitride semiconductor device 1 has, in plan view, a rectangular shape that has two sides parallel to the X direction and two sides parallel to the Y direction and is long in the X direction.

The nitride semiconductor device 1 includes the conductive SiC substrate 2 that has a first surface (front surface) 2a and a second surface (rear surface) 2b at an opposite side thereto, a semi-insulating SiC layer 3 (see FIG. 1 and FIG. 4) that is formed in a portion of a surface layer portion at the first surface 2a side of the conductive SiC substrate 2, and a nitride epitaxial layer 40 that is formed on the first surface 2a of the conductive SiC substrate 2 such as to cover the semi-insulating SiC layer 3. The nitride epitaxial layer 40 that is formed on the semi-insulating SiC layer 3 is formed on a silicon plane of the semi-insulating SiC layer 3.

The nitride epitaxial layer 40 includes a buffer layer 4 that is formed on the first surface 2a of the substrate 2, a semi-insulating nitride layer 5 that is formed on the buffer layer 4, a first nitride semiconductor layer 6 that is formed on the semi-insulating nitride layer 5, and a second nitride semiconductor layer 7 that is formed on the first nitride semiconductor layer 6.

From a standpoint of suppressing occurrence of warping of the conductive SiC substrate 2 and generation of internal cracks in the nitride epitaxial layer 40, a film thickness of the nitride epitaxial layer 40 is preferably not more than 4 μm and more preferably not more than 2.5 μm.

Further, the nitride semiconductor device 1 includes a passivation film 8 that is formed on the second nitride semiconductor layer 7. Further, the nitride semiconductor device 1 includes a plurality of the source electrodes 11, a drain electrode 12, and a gate electrode 13 that are formed on the passivation film 8. The respective source electrodes 11 are disposed in parallel to the Y direction at intervals in the X direction. Each source electrode 11 includes a source main electrode portion (first source metal) 11A, plug portions 11B arranged to electrically connect the source main electrode portion 11A to the conductive SiC substrate 2, and the extension portion (second source metal) 11C that extends upward from the source main electrode portion 11A. The extension portion 11C of the source electrode 11 has a metal as a frontmost layer and is also formed to improve heat dissipation by increasing a volume of the metal.

The drain electrode 12 includes a plurality of drain main electrode portions 12A that are each disposed between two adjacent source electrodes 11 and a base portion 12B that couples one end portions (+Y side end portions) of the drain main electrode portions 12A. In plan view, the base portion 12B is of a rectangular shape that is elongate in the X direction and is disposed further to the +Y side than +Y side end portions of the plurality of source electrodes 11. The plurality of drain main electrode portions 12A extend in comb teeth shape in the −Y direction from a −Y direction side edge of the base portion 12B. Each drain main electrode portion 12A is of a rectangular shape that is elongate in the Y direction in plan view.

The gate electrode 13 includes a plurality of gate main electrode portions 13A that are each disposed between a source electrode 11 and a drain main electrode portion 12A adjacent thereto and a base portion 13B that couples one end portions (−Y side end portions) of the gate main electrode portions 13A. In plan view, the base portion 13B is of a rectangular shape that is elongate in the X direction and is disposed further to the −Y side than −Y side end portions of the plurality of source electrodes 11. The plurality of gate main electrode portions 13A extend in comb teeth shape in the +Y direction from a +Y direction side edge of the base portion 13B. Each gate main electrode portion 13A is of a rectangular shape that is elongate in the Y direction in plan view.

In the example of FIG. 1, the source electrodes 11 (S), the gate main electrode portions 13A (G), and the drain main electrode portions 12A (D) are disposed cyclically in an order of SGDGSGDG in the X direction. Thereby, element structures are arranged in each of which a gate principal electrode portion 13A (G) is disposed between a source electrode 11 (S) and a drain principal electrode portion 12A (D).

As shown in FIG. 1, a region of a front surface of the nitride epitaxial layer 40 has an active region 110 in which a two-dimensional electron gas (2DEG) 19 to be described below can form and an inactive region 120 in which the two-dimensional electron gas 19 is not formed. In the example of FIG. 1, the inactive region 120 includes a first inactive region 121 at a peripheral edge portion of the front surface of the nitride epitaxial layer 40 and a plurality of second inactive regions 122 that are formed in island shapes inside the active region 110. In FIG. 1, dot hatching is applied to the inactive region 120 for clarity.

The plurality of second inactive regions 122 are formed in regions between the respective source electrodes 11 and the base portion 12B of the drain electrode 12. The second inactive regions 122 are formed to reduce a leak current between a drain and a source when a transistor (an HEMT to be described below) is off.

The first inactive region 121 includes a −X side region 121A corresponding to a −X side edge portion of the front surface of the nitride epitaxial layer 40 and a +X side region 121B corresponding to a +X side edge portion of the front surface of the nitride epitaxial layer 40. The first inactive region 121 further includes a −Y side region 121C that couples −Y side end portions of the −X side region 121A and the +X side region 121B to each other and a +Y side region 121D that couples+Y side end portions of the −X side region 121A and the +X side region 121B to each other.

The active region 110 is a region of the region of the front surface of the nitride epitaxial layer 40 besides the inactive region 120. The source electrodes 11, the drain electrode 12, and the gate electrode 13 are formed inside the active region 110. The base portion 12B of the drain electrode 12 is formed, inside the active region 110, along a −Y side edge of the +Y side region 121D of the first inactive region 121. The base portion 13B of the gate electrode 13 is formed, inside the active region 110, along a +Y side edge of the −Y side region 121C of the first inactive region 121.

The nitride semiconductor device 1 further includes the interlayer insulating film 9 that is formed on the passivation film 8 such as to cover the source main electrode portions 11A, the drain electrode 12, and the gate electrode 13. The passivation film 8 and the interlayer insulating film 9 are each an example of an “insulating film” of the present invention. The nitride semiconductor device 1 further includes the extension portions 11C of the source electrodes 11, the drain pad 21, and the gate pad 22 that are formed on the interlayer insulating film 9. The nitride semiconductor device 1 further includes a source pad (back electrode) 23 that is formed on the second surface 2b of the conductive SiC substrate 2.

The extension portion 11C of each source electrode 11 in plan view is of a rectangular shape that is long in the Y direction and is disposed on a central portion of a front surface of the source main electrode portion 11A.

The drain pad 21 in plan view is of a rectangular shape that is long in the X direction and is disposed across the +Y side region 121D and the base portion 12B of the drain electrode 12 in a region between a +Y side edge of the +Y side region 121D of the first inactive region 121 and a −Y side edge of the base portion 12B. The drain pad 21 in plan view thus has a first pad region 21a that is disposed on the +Y side region 121D of the first inactive region 121, a second pad region 21b that is disposed on the base portion 12B, and a third region 21c that is sandwiched between the two. The first pad region 21a is an example of a “first drain pad region” in the present disclosure.

The gate pad 22 in plan view is of a rectangular shape that is long in the X direction and is disposed across the −Y side region 121C and the base portion 13B of the gate electrode 13 in a region between a −Y side edge of the −Y side region 121C of the first inactive region 121 and a +Y side edge of the base portion 13B. The gate pad 22 in plan view thus has a first pad region 22a that is disposed on the −Y side region 121C of the first inactive region 121, a second pad region 22b that is disposed on the base portion 13B, and a third region 22c that is sandwiched between the two. The first pad region 22a is an example of a “first gate pad region” in the present disclosure.

A resistivity of the conductive SiC substrate 2 is preferably not more than 0.01 Ω·cm. In this preferred embodiment, the resistivity of the conductive SiC substrate 2 is approximately 0.002 Ω·cm. A thickness of the conductive SiC substrate 2 is, for example, approximately 50 μm to 400 μm. In this preferred embodiment, the thickness of the conductive SiC substrate 2 is approximately 100 μm.

The semi-insulating SiC layer 3 includes a plurality of first semi-insulating SiC layers 31 that are disposed below the drain pad 21 in plan view and a plurality of second semi-insulating SiC layers 32 that are disposed below the gate pad 22 in plan view. The plurality of first semi-insulating SiC layers 31 are disposed side by side at intervals in the X direction inside a region below the drain pad 21 in plan view. Each first semi-insulating SiC layer 31 is of a quadrilateral shape (a rectangular shape that is long in the Y direction in the example of FIG. 1) in plan view and is disposed across the first pad region 21a and the second pad region 21b of the drain pad 21 in bottom view. Each first semi-insulating SiC layer 31 thus has a portion 31a that is disposed below the first pad region 21a of the drain pad 21.

The plurality of second semi-insulating SiC layers 32 are disposed side by side at intervals in the X direction inside a region below the gate pad 22 in plan view. Each second semi-insulating SiC layer 32 is of a quadrilateral shape (a rectangular shape that is long in the Y direction in the example of FIG. 1) in plan view and is disposed across the first pad region 22a and the second pad region 22b of the gate pad 22 in bottom view. Each second semi-insulating SiC layer 32 thus has a portion 32a that is disposed below the first pad region 22a of the gate pad 22.

In this preferred embodiment, the semi-insulating SiC layer 3 is constituted of just the plurality of first semi-insulating SiC layers 31 that are disposed inside the region below the drain pad 21 and the plurality of second semi-insulating SiC layers 32 that are disposed in the region below the gate pad 22.

A resistivity of the semi-insulating SiC layer 3 is preferably not less than 1 Ω·cm and is more preferably not less than 1×10³Ω·cm. In this preferred embodiment, the resistivity of the semi-insulating SiC layer 3 is approximately 5×10⁵Ω·cm. A thickness of the semi-insulating SiC layer 3 is, for example, approximately 1 μm to 50 μm. In this preferred embodiment, the thickness of the semi-insulating SiC layer 3 is approximately 20 μm.

The semi-insulating SiC layer 3 may be formed by irradiating an electron beam onto the surface layer portion of the conductive SiC substrate 2. The semi-insulating SiC layer 3 may be formed by doping the surface layer portion of the conductive SiC substrate 2 with protons. Also, the semi-insulating SiC layer 3 may be formed by implanting the surface layer portion of the conductive SiC substrate 2 with a group 13 element such as B, Al, Ga, In, etc. Also, the semi-insulating SiC layer 3 may be formed by doping the surface layer portion of the conductive SiC substrate 2 with a transition metal.

The semi-insulating SiC layer 3 may be formed by using, for example, a plasma CVD apparatus to form a film with which a donor of a shallow level constituted of N, P, etc., and an acceptor of a shallow level constituted of B, Al, etc., are adjusted to be 1×10¹⁷ cm⁻³. Also, the resistivity can be increased further by compensating a shallow level by introducing more of a deep level than a shallow level by doping of a metal element such as V, Ti, etc.

The buffer layer 4 is a buffering layer that is arranged to buffer strain resulting from mismatch of a lattice constant of the semi-insulating nitride layer 5 formed on the buffer layer 4 and a lattice constant of the conductive SiC substrate 2 (semi-insulating SiC layer 3). In this preferred embodiment, the buffer layer 4 is constituted of a multilayer buffer layer in which a plurality of nitride semiconductor films are laminated. In this preferred embodiment, the buffer layer 4 is constituted of a laminated film of an AlN film that is a lower layer and an AlGaN film that is an upper layer. The buffer layer 4 may instead be constituted of a single film of an AlN film or a single film of AlGaN. A thickness of the buffer layer 4 is, for example, approximately 0.01 μm to 1 μm. In this preferred embodiment, the thickness of the buffer layer 4 is approximately 0.1 μm.

The semi-insulating nitride layer 5 is provided to suppress a leak current. The semi-insulating nitride layer 5 is constituted of a GaN layer that is doped with an impurity and a thickness thereof is, for example, approximately 0.5 μm to 10 μm. In this preferred embodiment, the thickness of the semi-insulating nitride layer 5 is approximately 1 μm. The impurity is, for example, C (carbon) and is doped such that a difference (Na—Nd) between an acceptor concentration Na and a donor concentration Nd is approximately 1×10¹⁷ cm⁻³.

The first nitride semiconductor layer 6 constitutes an electron transit layer. In this preferred embodiment, the first nitride semiconductor layer 6 is constituted of an n-type GaN layer that is doped with a donor type impurity and a thickness thereof is, for example, approximately 0.05 μm to 1 μm. In this preferred embodiment, the thickness of the first nitride semiconductor layer 6 is approximately 0.2 μm. Also, the first nitride semiconductor layer 6 may be constituted of an undoped GaN layer instead.

In regard to the first nitride semiconductor layer 6, a lower surface at the semi-insulating nitride layer 5 side shall be referred to as a rear surface and an upper surface at an opposite side thereto shall be referred to as a front surface. Also, a region of the front surface of the first nitride semiconductor layer 6 corresponding to the first inactive region 121 of FIG. 1 shall be referred to as a peripheral edge portion of the front surface of the first nitride semiconductor layer 6. A central portion that is surrounded by the peripheral edge portion of the front surface of the first nitride semiconductor layer 6 protrudes further upward than the peripheral edge portion of the front surface of the first nitride semiconductor layer 6 with the exception of regions corresponding to the second inactive regions 122. In the central portion of the front surface of the first nitride semiconductor layer 6, an inactive region recess portion (not shown) of quadrilateral shape in plan view is formed in each of the regions corresponding to the second inactive regions 122.

A step is thereby formed between the central portion and the peripheral edge portion of the front surface of the first nitride semiconductor layer 6. Steps (not shown) are also formed between a region of the central portion of the front surface of the first nitride semiconductor layer 6 in which the inactive region recess portions are not formed and bottom surfaces of the inactive region recess portions. The front surface (upper surface) of the first nitride semiconductor layer 6 thus includes a high step portion 5A that is substantially an entirety of the central portion, a first low step portion 5B that is the peripheral edge portion, a first connecting portion 5C that connects the high step portion 5A and the first low step portion 5B, second low step portions (not shown) that are constituted of bottom surfaces of the inactive region recess portions, and second connecting portions (not shown) that connect the high step portion 5A and the second low step portions. The second low step portions are at the same height position as the first low step portion 5B. In other words, a height difference between the high step portion 5A and the second low step portions and a height difference between the high step portion 5A and the first low step portion 5B are equal.

The second nitride semiconductor layer 7 is formed on the high step portion 5A of the first nitride semiconductor layer 6. In other words, the second nitride semiconductor layer 7 is formed on a region of the front surface of the first nitride semiconductor layer 6 excluding the first low step portion 5B and the second low step portions. The second nitride semiconductor layer 7 constitutes an electron supply layer. In the second nitride semiconductor layer 7, inactive region penetrating holes (not shown) that are in communication with the respective inactive region recess portions of the first nitride semiconductor layer 6 are formed at positions corresponding to the respective inactive region recess portions in plan view.

The second nitride semiconductor layer 7 is constituted of a nitride semiconductor of greater bandgap than the first nitride semiconductor layer 6. Specifically, the second nitride semiconductor layer 7 is constituted of a nitride semiconductor of higher Al composition than the first nitride semiconductor layer 6. In a nitride semiconductor, the higher the Al composition, the greater the bandgap. In this preferred embodiment, the second nitride semiconductor layer 7 is constituted of an AlₓGa₁₋ₓN layer (0<x≤1) and a thickness thereof is, for example, approximately 0.001 μm to 0.1 μm. In this preferred embodiment, the thickness of the second nitride semiconductor layer 7 is approximately 0.02 μm and x=0.2.

The first nitride semiconductor layer 6 (electron transit layer) and the second nitride semiconductor layer 7 (electron supply layer) are thus constituted of nitride semiconductors that differ in bandgap (Al composition) and a lattice mismatch occurs therebetween. Also, due to spontaneous polarizations of the first nitride semiconductor layer 6 and the second nitride semiconductor layer 7 and a piezo polarization due to the lattice mismatch between the two, an energy level of a conduction band of the first nitride semiconductor layer 6 at an interface between the first nitride semiconductor layer 6 and the second nitride semiconductor layer 7 is made lower than a Fermi level. Thereby, inside the first nitride semiconductor layer 6, the two-dimensional electron gas 19 spreads at a position close to the interface with the second nitride semiconductor layer 7 (for example, at a distance of approximately several A from the interface).

Although the two-dimensional electron gas 19 is formed in a portion of the front surface of the first nitride semiconductor layer 6 below the high step portion 5A, the two-dimensional electron gas 19 is not formed in portions below the first low step portion 5B and the second low step portions. Therefore, in plan view, a region corresponding to the high step portion 5A becomes the active region 110 and regions corresponding to the first low step portion 5B and the second low step portions become the inactive region 120. The inactive region 120 is constituted of the first inactive region 121 that is a region corresponding to the first low step portion 5B and the second inactive regions 122 corresponding to the second low steps.

The passivation film 8 is formed across substantially an entirety of a front surface of the second nitride semiconductor layer 7. In this preferred embodiment, the passivation film 8 is constituted of SiN. A thickness of the passivation film 8 is, for example, approximately 0.05 μm to 0.3 μm. In this preferred embodiment, the thickness of the passivation film 8 is approximately 0.1 μm. Besides SiN, the passivation film 8 may be constituted of SiO₂, SiN, SiON, Al₂O₃, AlN, AlON, HfO, HfN, HfON, HfSiON, AlON, etc.

A plurality of source contact holes 14, a drain contact hole 15, and a gate contact hole 16 are formed in the passivation film 8. The contact holes 14, 15, and 16 penetrate through the passivation film 8 in the thickness direction. As shown in FIG. 2, the plurality of source contact holes 14 include a pair of source contact holes 14 that are formed according to each source electrode 11 and extend in parallel in the Y direction.

As shown in FIG. 2, the drain contact hole 15 in plan view is constituted of first portions 15A that are formed in regions of the passivation film 8 facing central portions of the respective drain main electrode portions 12A and a second portion 15B that is formed in a region of the passivation film 8 corresponding to a central portion of the base portion 12B. A +Y side end of each first portion 15A is in communication with the second portion 15B.

As shown in FIG. 2, the gate contact hole 16 in plan view is constituted of first portions 16A that are formed in regions of the passivation film 8 facing central portions of the respective gate main electrode portions 13A and a second portion 16B that is formed in a region of the passivation film 8 corresponding to a central portion of the base portion 13B. A −Y side end of each first portion 16A is in communication with the second portion 16B.

In the conductive SiC substrate 2, the nitride epitaxial layer 40, and the passivation film 8, back contact holes 17 that penetrate continuously through the passivation film 8 and the nitride epitaxial layer 40 from a front surface of the passivation film 8 and extend to an intermediate thickness of the conductive SiC substrate 2 are formed, each at a central position between the pair of source contact holes 14 formed for each source electrode 11. The back contact holes 17 are formed in plurality (three in the example of FIG. 1) at intervals in the Y direction at the central position between each pair of source contact holes 14 in plan view.

The source main electrode portion 11A of each source electrode 11 is formed on the passivation film 8 such as to cover the pair of source contact holes 14. Portions of the source main electrode portion 11A enter into the pair of source contact holes 14 and are in ohmic contact with the front surface of the second nitride semiconductor layer 7 inside the source contact holes 14. The plug portions 11B of the source electrode 11 are embedded inside the back contact holes 17 and the source main electrode portion 11A is electrically connected to the conductive SiC substrate 2. The plug portions 11B are an example of a “conductive member that electrically connects the source electrode and the conductive SiC substrate” in the present disclosure.

The drain electrode 12 is formed on the passivation film 8 such as to cover the drain contact hole 15. A portion of the drain electrode 12 enters into the drain contact hole 15 and is in ohmic contact with the front surface of the second nitride semiconductor layer 7 inside the drain contact hole 15.

The source electrodes 11 and the drain electrode 12 are constituted, for example, of Au. A thickness of the source main electrode portions 11A and the drain electrode 12 is approximately 5 μm. Also, the source electrodes 11 and the drain electrode 12 suffice to be constituted of a material with which ohmic contact can be established with respect to the second nitride semiconductor layer 7 (AlGaN layer).

The gate electrode 13 is formed on the passivation film 8 such as to cover the gate contact hole 16. A portion of the gate electrode 13 enters into the gate contact hole 16 and is in Schottky contact with the front surface of the second nitride semiconductor layer 7 inside the gate contact hole 16.

The gate electrode 13 is constituted, for example, of an Ni/Au laminated film in which an Ni film and an Au film are laminated in that order from a lower layer. A thickness of the Ni film at the lower layer side is, for example, approximately 10 nm and a thickness of the Au film at an upper layer side is, for example, approximately 600 nm. The gate electrode 13 suffices to be constituted of a material with which a Schottky barrier can be formed with respect to the second nitride semiconductor layer 7 (AlGaN layer).

The source via holes 24 that expose the central portions of the front surfaces of the source main electrode portions 11A in plan view are formed in the interlayer insulating film 9. Also, the drain via hole 25 that exposes a central portion of a front surface of the base portion 12B in plain view is formed in the interlayer insulating film 9. Further, the gate via hole 26 that exposes a central portion of a front surface of the base portion 13B in plain view is formed in the interlayer insulating film 9.

The extension portion 11C of each source electrode 11 is formed on the interlayer insulating film 9 such as to cover the source via hole 24. A portion of the extension portion 11C of the source electrode 11 enters into the source via hole 24 and is connected to the source main electrode portion 11A inside the source via hole 24.

The drain pad 21 is formed on the interlayer insulating film 9 such as to cover the drain via hole 25. A portion of the drain pad 21 enters into the drain via hole 25 and is connected to the base portion 12B inside the drain via hole 25.

The gate pad 22 is formed on the interlayer insulating film 9 such as to cover the gate via hole 26. A portion of the gate pad 22 enters into the gate via hole 26 and is connected to the base portion 13B inside the gate via hole 26.

The extension portions 11C of the source electrodes 11, the drain pad 21, and the gate pad 22 are constituted, for example, of Au. A thickness of these is, for example, approximately 3 μm.

The source pad (back electrode) 23 is constituted, for example, of Ni. A film thickness of the source pad 23 is, for example, approximately 100 nm.

With the nitride semiconductor device 1, a heterojunction is formed by there being formed, on the first nitride semiconductor layer 6 (electron transit layer), the second nitride semiconductor layer 7 (electron supply layer) that differs in bandgap (Al composition). Thereby, inside the active region 110, the two-dimensional electron gas 19 is formed inside the first nitride semiconductor layer 6 near the interface of the first nitride semiconductor layer 6 and the second nitride semiconductor layer 7 and an HEMT (high electron mobility transistor) that uses the two-dimensional electron gas 19 as a channel is formed.

In a state where a control voltage is not applied to the gate electrode 13, the source electrodes 11 and the drain electrode 12 are connected to each other with the two-dimensional electron gas 19 as the channel. Therefore, the HEMT is of a normally-on type. When the control voltage such that a potential at the gate electrode 13 is made negative with respect to the source electrodes 11 is applied to the gate electrode 13, the two-dimensional electron gas 19 is interrupted and the HEMT is put in an off state.

With this preferred embodiment, since the semi-insulating SiC layer 3 is formed in the portion of the surface layer portion of the conductive SiC substrate 2, a parasitic capacitance can be reduced in comparison to a case where the semi-insulating SiC layer 3 is not formed in the surface layer portion of the conductive SiC substrate 2. Although when the conductive SiC substrate 2 is used, the film thickness of the nitride epitaxial layer 40 needs to be made large to reduce the parasitic capacitance, with this preferred embodiment, it is made possible to make the film thickness of the nitride epitaxial layer 40 small. Suppression of warping of the conductive SiC substrate 2 and internal cracks in the nitride epitaxial layer 40 and reduction of parasitic capacitance are thereby enabled.

In this preferred embodiment, a parasitic capacitance (hereinafter referred to as the “first parasitic capacitance”) occurs readily between the drain pad 21 and the conductive SiC substrate 2. In the active region 110, the first parasitic capacitance is small because the two-dimensional electron gas 19 is generated between the drain pad 21 and the conductive SiC substrate 2. On the other hand, in the inactive region 120, there is a possibility for the first parasitic capacitance to become large because the two-dimensional electron gas 19 is not generated between the drain pad 21 and the conductive SiC substrate 2.

In this preferred embodiment, the plurality of first semi-insulating SiC layers 31 that are disposed below the drain pad 21 each have the portion 31a that is disposed below the first pad region 21a of the drain pad 21. A distance between the first pad region 21a and a boundary surface of the conductive SiC substrate 2 with respect to a lower surface of each first semi-insulating SiC layer 31 is thereby made long. The first parasitic capacitance in the inactive region 120 can thereby be reduced. Since a drain-source capacitance Cds can thereby be reduced, an output capacitance Coss can be reduced.

Also, in this preferred embodiment, a parasitic capacitance (hereinafter referred to as the “second parasitic capacitance”) occurs readily between the gate pad 22 and the conductive SiC substrate 2. In the active region 110, the second parasitic capacitance is small because the two-dimensional electron gas 19 is generated between the gate pad 22 and the conductive SiC substrate 2. On the other hand, in the inactive region 120, there is a possibility for the second parasitic capacitance to become large because the two-dimensional electron gas 19 is not generated between the gate pad 22 and the conductive SiC substrate 2.

In this preferred embodiment, the plurality of second semi-insulating SiC layers 32 that are disposed below the gate pad 22 each have the portion 32a that is disposed below the first pad region 22a of the gate pad 22. A distance between the first pad region 22a and a boundary surface of the conductive SiC substrate 2 with respect to a lower surface of each second semi-insulating SiC layer 32 is thereby made long. The second parasitic capacitance in the inactive region 120 can thereby be reduced. Since a gate-source capacitance Cgs can thereby be reduced, an input capacitance Ciss can be reduced.

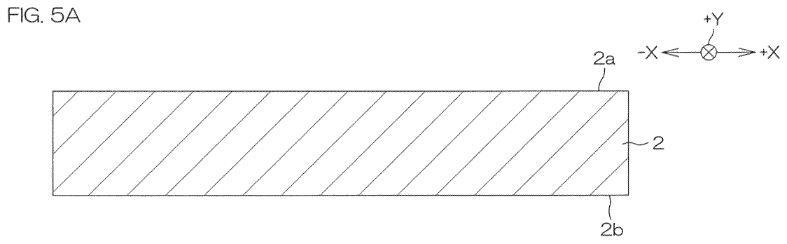

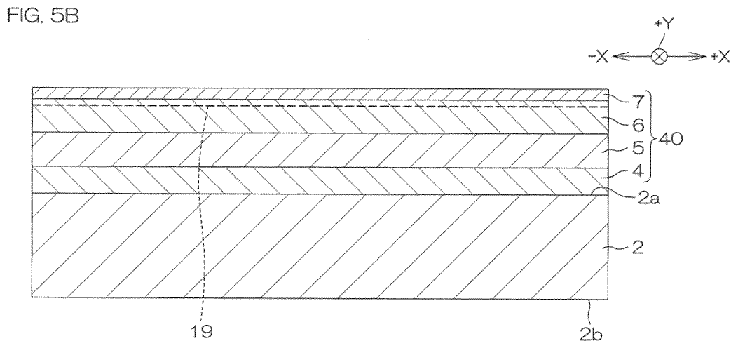

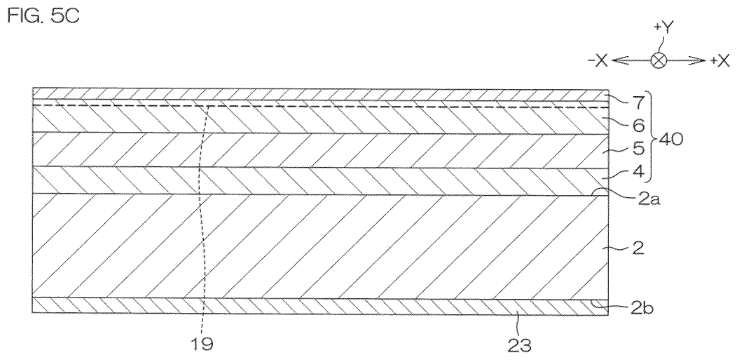

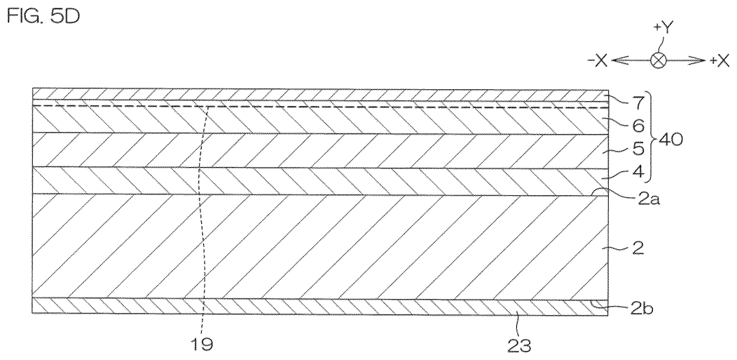

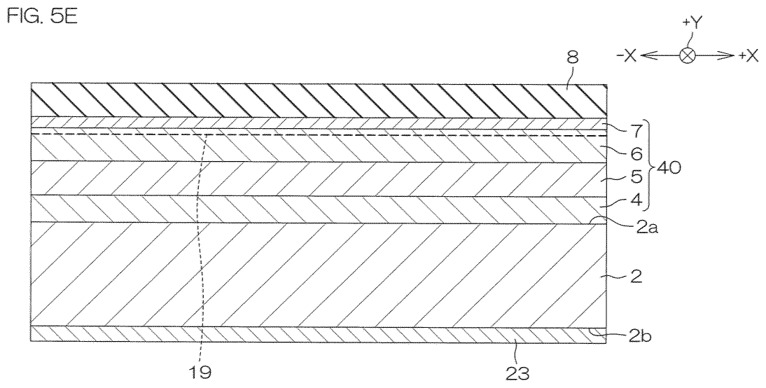

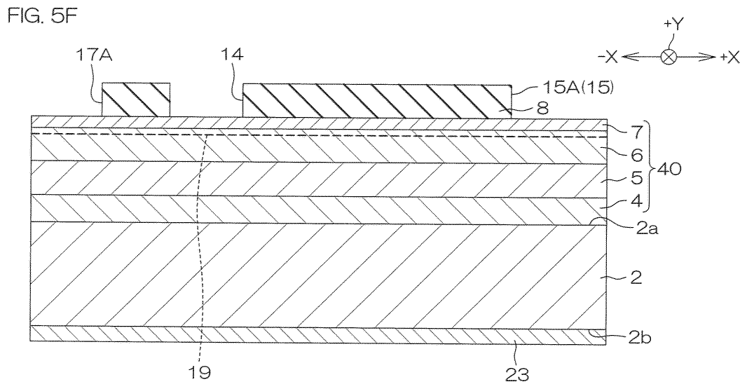

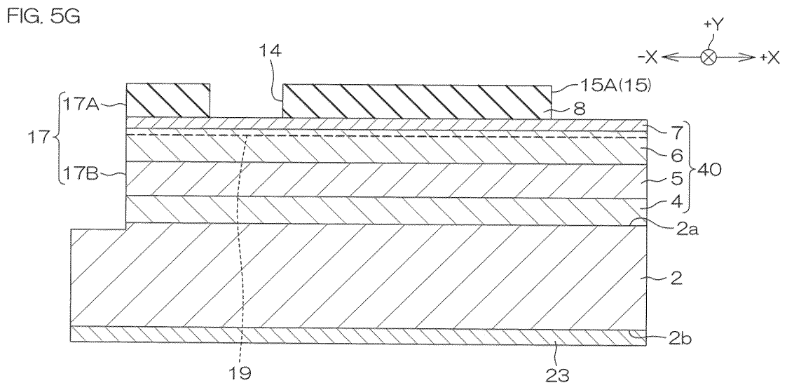

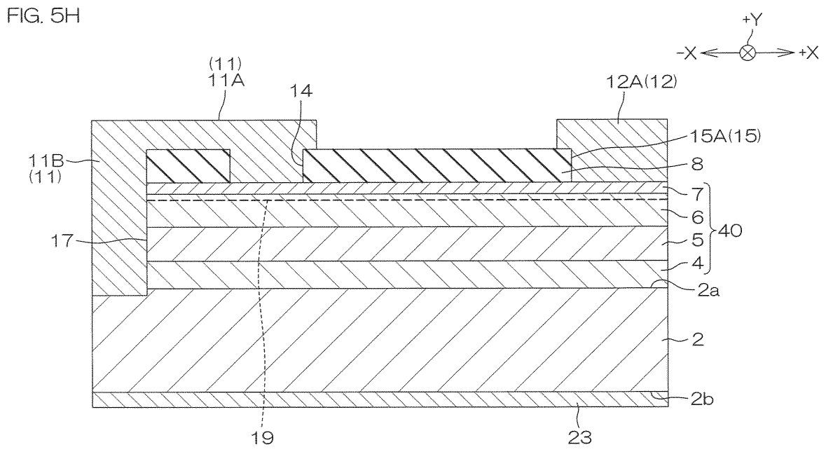

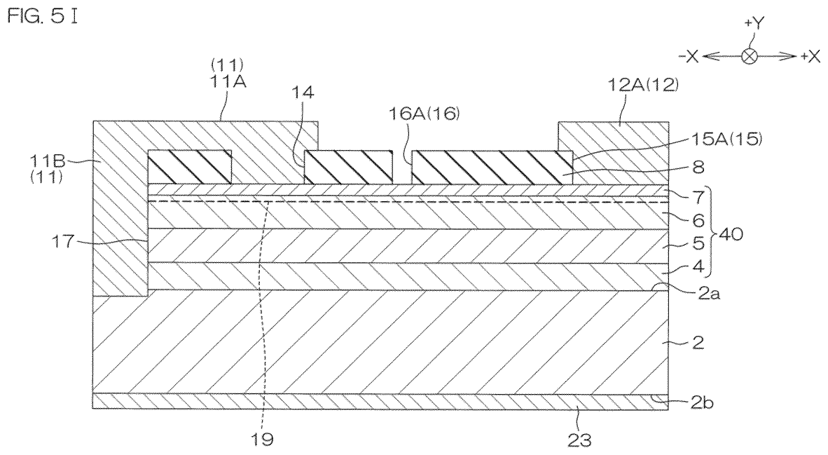

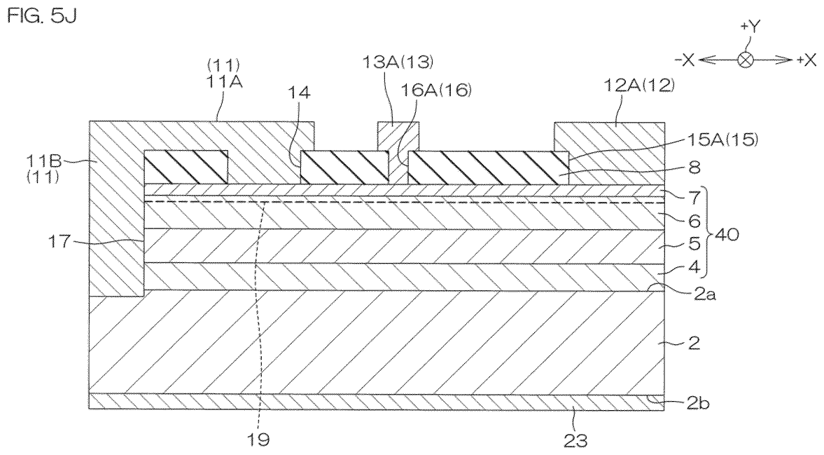

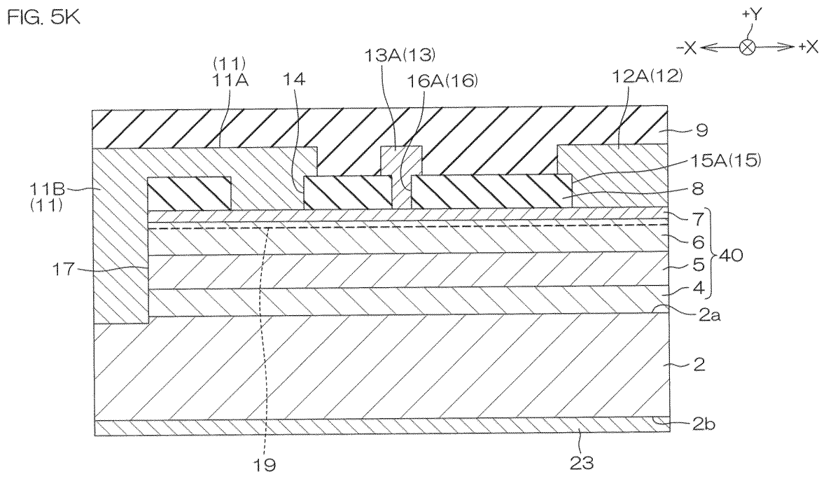

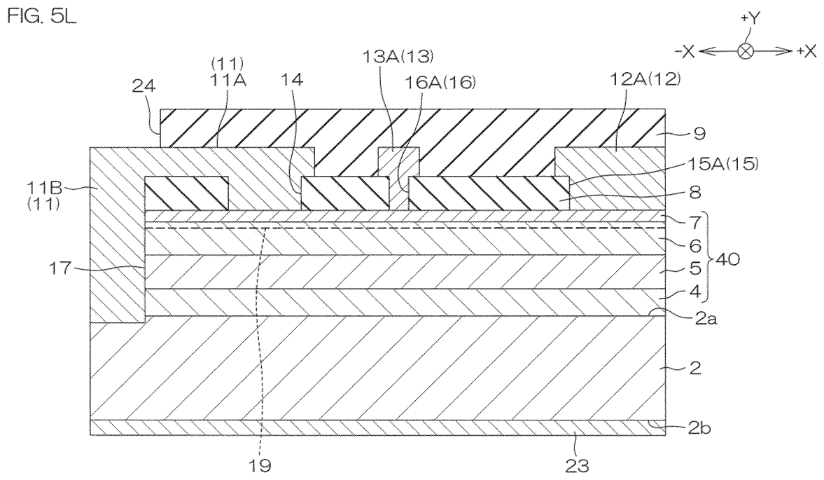

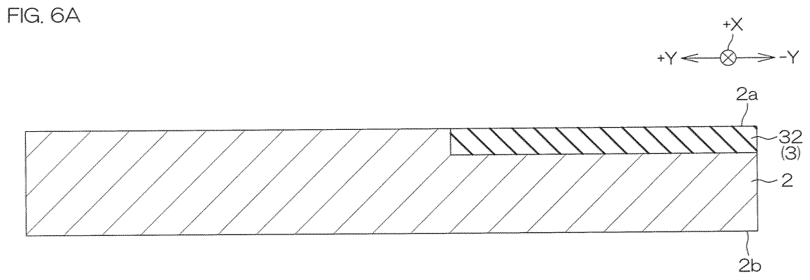

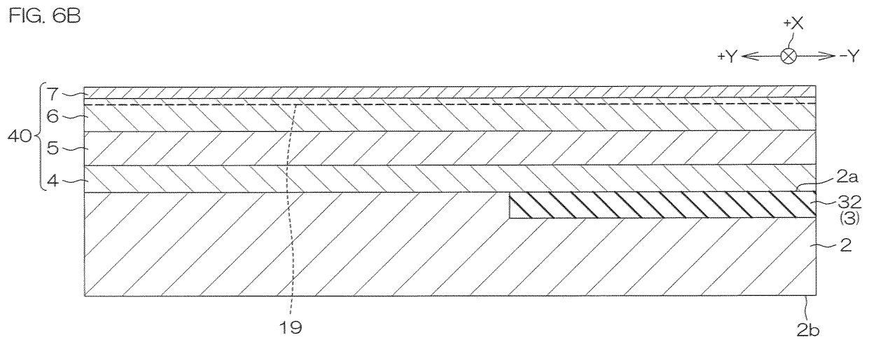

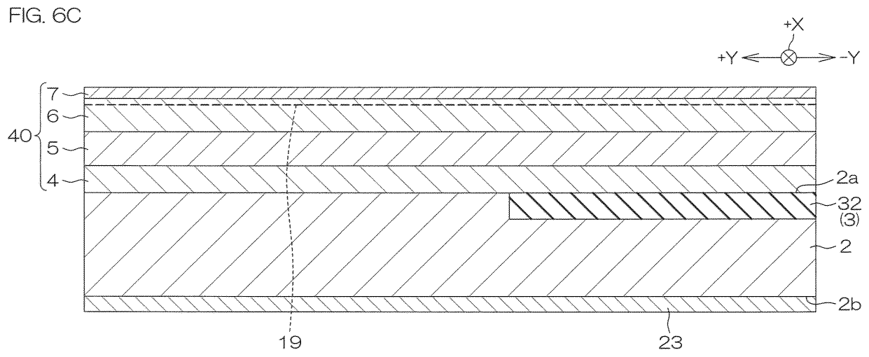

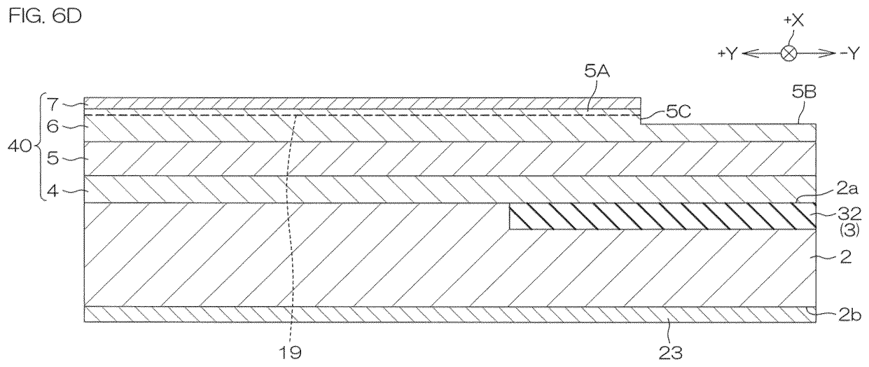

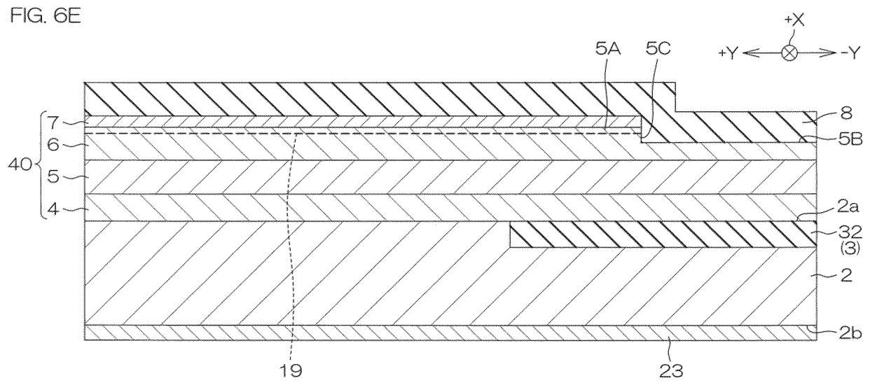

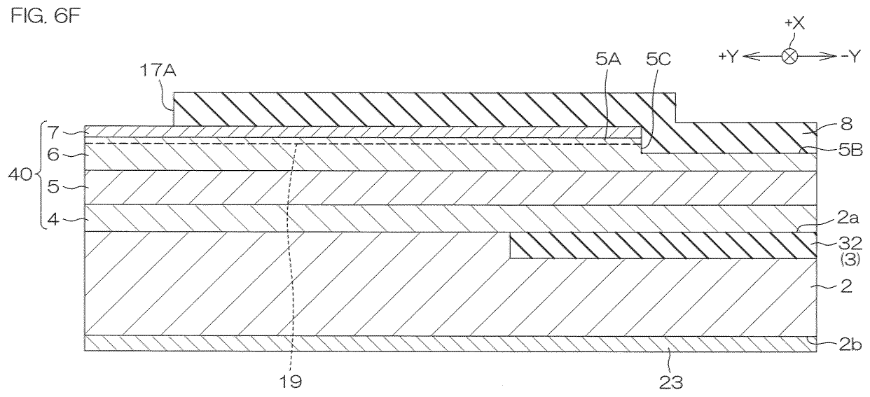

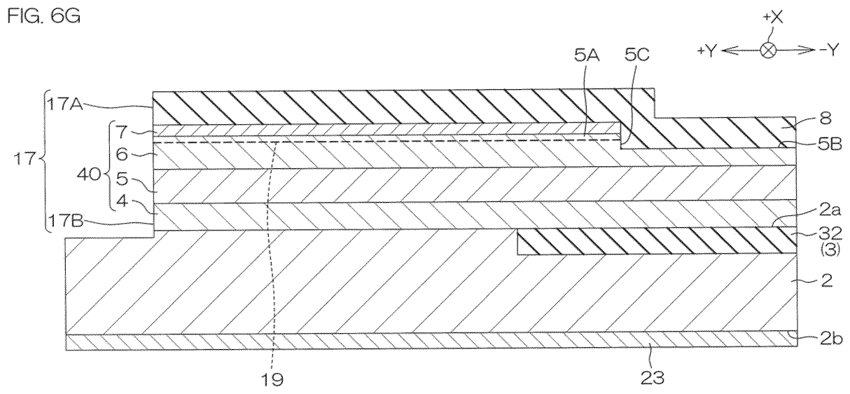

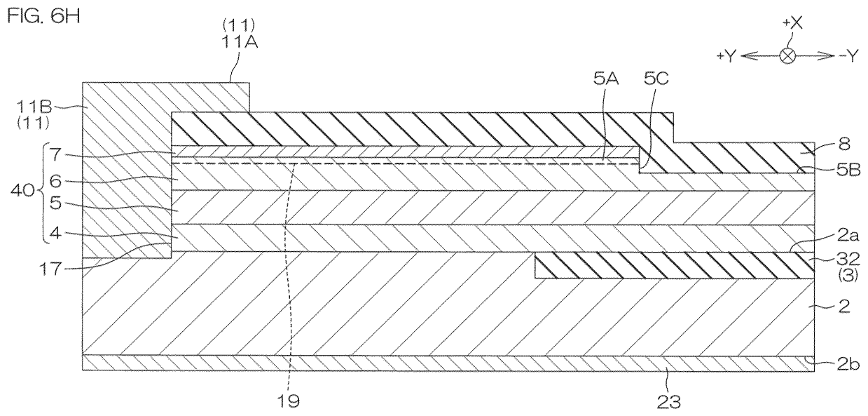

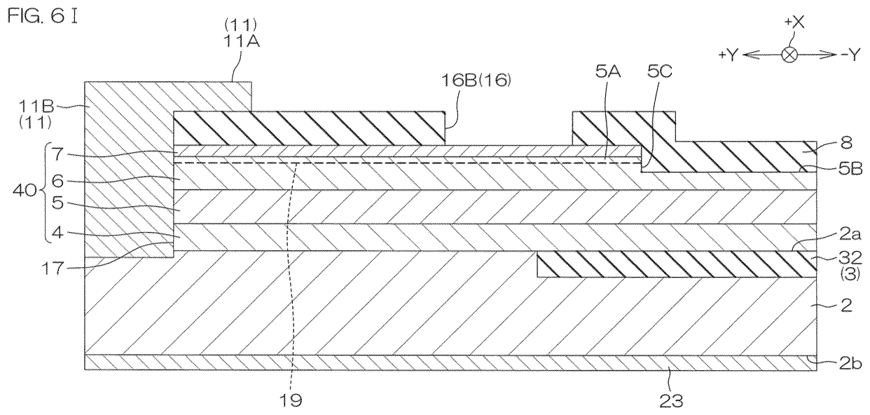

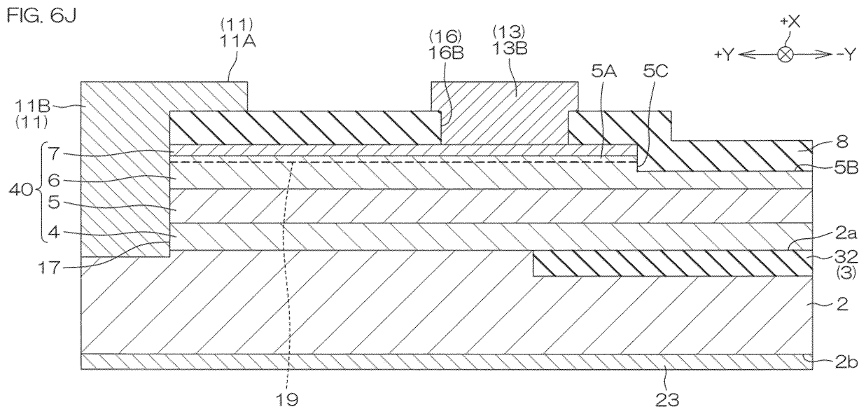

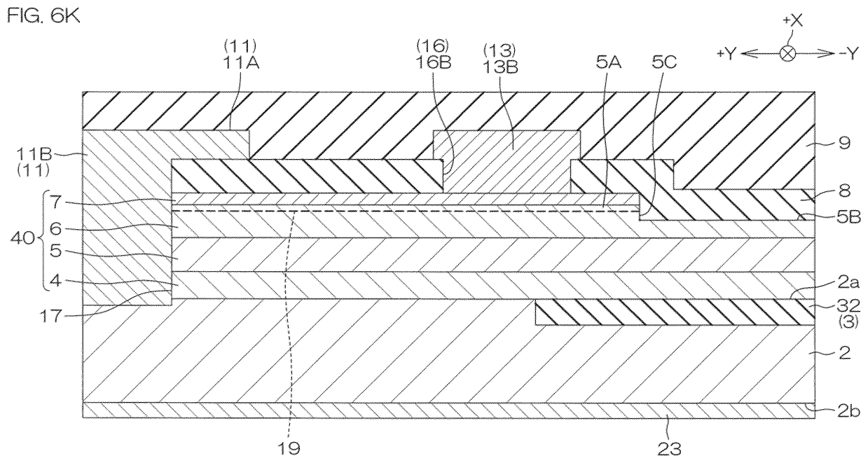

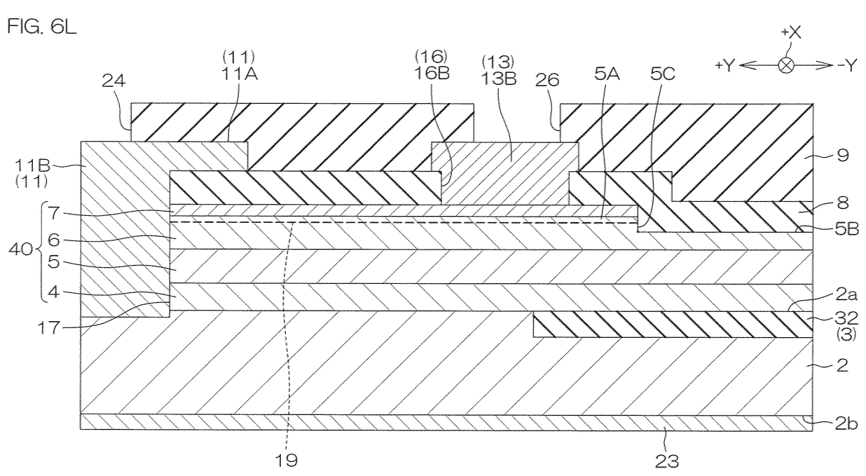

FIG. 5A to FIG. 5L are illustrative sectional views sequentially showing a manufacturing process of the nitride semiconductor device 1 shown in FIG. 1 to FIG. 4 and are sectional views corresponding to the section plane of FIG. 3. FIG. 6A to FIG. 6L are illustrative sectional views sequentially showing the manufacturing process of the nitride semiconductor device 1 described above and are sectional views corresponding to the section plane of FIG. 4.

First, as shown in FIG. 5A and FIG. 6A, the semi-insulating SiC layer 3 is formed selectively in the surface layer portion of the conductive SiC substrate 2 at the first surface 2a side. The semi-insulating SiC layer 3 is constituted of the plurality of first semi-insulating SiC layers 31 and the plurality of second semi-insulating SiC layers 32. The semi-insulating SiC layer 3 is formed, for example, by irradiating an electron beam onto the surface layer portion at the first surface 2a side of the conductive SiC substrate 2.

Next, as shown in FIG. 5B and FIG. 6B, the buffer layer 4 is epitaxially grown, for example, by an MOCVD (metal organic chemical vapor deposition) method on the first surface 2a of the conductive SiC substrate 2 such as to cover the semi-insulating SiC layer 3. Further, the semi-insulating nitride layer 5, the first nitride semiconductor layer (electron transit layer) 6, and the second nitride semiconductor layer (electron supply layer) 7 are epitaxially grown successively on the buffer layer 4. The nitride epitaxial layer 40 constituted of the buffer layer 4, the semi-insulating nitride layer 5, the first nitride semiconductor layer 6, and the second nitride semiconductor layer 7 is thereby formed on the first surface 2a of the conductive SiC substrate 2.

Next, as shown in FIG. 5C and FIG. 6C, the source pad 23 is formed on the second surface 2b of the conductive SiC substrate 2, for example, by a sputtering method. The source pad 23 is constituted, for example, of Ni.

Next, as shown in FIG. 5D and FIG. 6D, a resist film (not shown) that covers a region directly above a planned formation region of the high step portion 5A of the front surface of the first nitride semiconductor layer 6 is formed on the second nitride semiconductor layer 7. By dry etching using the resist film as a mask, a peripheral edge portion of the second nitride semiconductor layer 7 is removed and a peripheral edge portion of the first nitride semiconductor layer 6 is removed down to an intermediate thickness. Also, the plurality of inactive region penetrating holes are formed in the second nitride semiconductor layer 7 and the plurality of inactive region recess portions that are in communication with the penetrating holes are formed in the first nitride semiconductor layer 6. The front surface of the first nitride semiconductor layer 6 is thereby made to be arranged from the high step portion 5A, the first low step portion 5B, the first connecting portion 5C connecting the high step portion 5A and the first low step portion 5B, the second low portions (not shown), and the second connecting portions connecting the high step portion 5A and the second low step portions. As an etching gas, for example, a chlorine-based gas such as Cl₂, BCl₃, SiCl₄, etc., is used.

The active region 110 in which the two-dimensional electron gas 19 can form and the inactive region 120 (121, 122) in which the two-dimensional electron gas 19 is not formed are thereby formed.

Here, the etching may be performed until an etching bottom surface reaches an upper surface of the semi-insulating nitride layer 5 or may be performed until it reaches an intermediate thickness of the semi-insulating nitride layer 5. Also, the etching may be performed until the etching bottom surface reaches an upper surface of the buffer layer 4 or may be performed until it reaches an intermediate thickness of the buffer layer 4.

Next, as shown in FIG. 5E and FIG. 6E, the passivation film 8 is formed by a plasma CVD method, LPCVD (low pressure CVD) method, MOCVD method, sputtering method, etc., such as to cover exposed surfaces of the first nitride semiconductor layer 6 and exposed surfaces of the second nitride semiconductor layer 7.

Next, as shown in FIG. 5F and FIG. 6F, a resist film (not shown) is formed on the passivation film 8 at a region excluding regions in which the back contact holes 17, the source contact holes 14, and the drain contact hole 15 are to be formed. By the passivation film 8 being, for example, dry etched via the resist film, portions 17A of the back contact holes 17, the source contact holes 14, and the drain contact hole 15 (15A, 15B) are formed in the passivation film 8. Thereafter, the resist film is removed.

The portions 17A of the back contact holes 17, the source contact holes 14, and the drain contact hole 15 penetrate through the passivation film 8 and reach the second nitride semiconductor layer 7. Widths of the source contact holes 14 and the drain contact hole 15 are approximately 3 μm to 5 μm. As the etching gas, for example, CF₄ gas is used. Also, SF₆ gas, CHF₃ gas, etc., may be used in place of CF₄ gas.

Next, as shown in FIG. 5G and FIG. 6G, a resist film (not shown) is formed on the passivation film 8 at a region excluding regions in which the back contact holes 17 are to be formed. Portions of the nitride epitaxial layer 40 and the conductive SiC substrate 2 are etched, for example, by dry etching via the resist film.

Thereby, holes 17B that penetrate through the nitride epitaxial layer 40 and reach the conductive SiC substrate 2 interior, in other words, the remaining portions 17B of the back contact holes 17 are formed. The back contact holes 17 each constituted of the portion 17A and the remaining portion 17B are thereby obtained. As the etching gas, for example, BCl₃ gas is used. Also, Cl₂ gas, SiCl₄ gas, etc., may be used in place of BCl₃ gas. Thereafter, the resist film is removed.

Next, as shown in FIG. 5H and FIG. 6H, the source main electrode portions 11A and the plug portions 11B of the source electrodes 11 and the drain electrode 12 are formed, for example, by an Au plating method. The source main electrode portions 11A and the plug portions 11B are formed by Au films being formed by plating such as to fill the source contact holes 14 and the back contact holes 17. The drain electrode 12 is formed by an Au film being formed by plating such as to fill the drain contact hole 15.

Next, as shown in FIG. 5I and FIG. 6I, a resist film (not shown) is formed on the passivation film 8 at a region excluding a region in which the gate contact hole 16 is to be formed. By the passivation film 8 being, for example, dry etched via the resist film, the gate contact hole 16 (16A, 16B) is formed in the passivation film 8. As the etching gas, for example, CF₄ gas is used. Also, SF₆ gas, CHF₃ gas, etc., may be used in place of CF₄ gas. Thereafter, the resist film is removed.

Next, as shown in FIG. 5J and FIG. 6J, the gate electrode 13 is formed, for example, by a lift-off method. Specifically, a resist film (not shown) is formed on the passivation film 8 at a region excluding a region in which the gate electrode 13 is to be formed. After an Ni/Au laminated film is vapor-deposited using the resist film as a mask, the resist film is removed.

Next, as shown in FIG. 5K and FIG. 6K, the interlayer insulating film 9 is formed, for example, by a CVD method or a sputtering method on the passivation film 8 such as to cover the source main electrode portions 11A, the drain electrode 12, and the gate electrode 13.

Next, as shown in FIG. 5L and FIG. 6L, a resist film (not shown) is formed on the interlayer insulating film 9 at a region excluding regions in which the source via holes 24, the drain via hole 25, and the gate via hole 26 are to be formed. By the interlayer insulating film 9 being, for example, dry etched via the resist film, the source via holes 24, the drain via hole 25, and the gate via hole 26 are formed in the interlayer insulating film 9. As the etching gas, for example, CF₄ gas is used. Also, SF₆ gas, CHF₃ gas, etc., may be used in place of CF₄ gas. Thereafter, the resist film is removed.

Lastly, the extension portions 11C of the source electrodes 11, the drain pad 21, and the gate pad 22 are formed, for example, by an Au plating method. The extension portions 11C are formed by Au films being formed by plating such as to fill the source via holes 24. The drain pad 21 and the gate pad 22 are respectively formed by Au films being formed by plating such as to fill the drain via hole 25 and the gate via hole 26. The nitride semiconductor device 1 shown in FIG. 1 to FIG. 4 is thereby obtained.

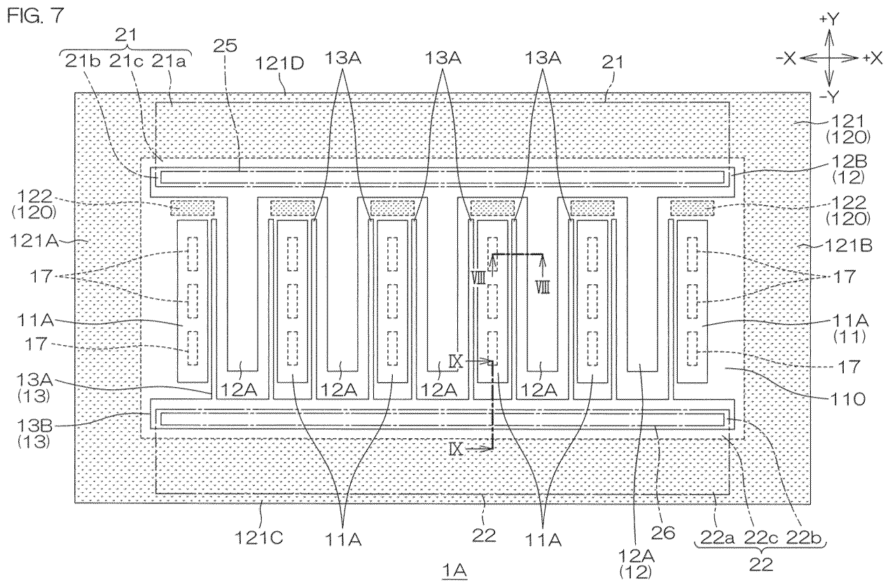

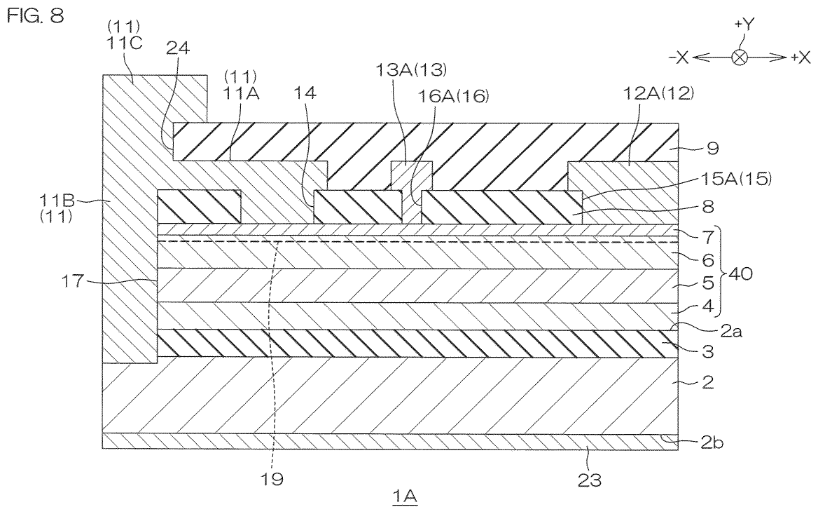

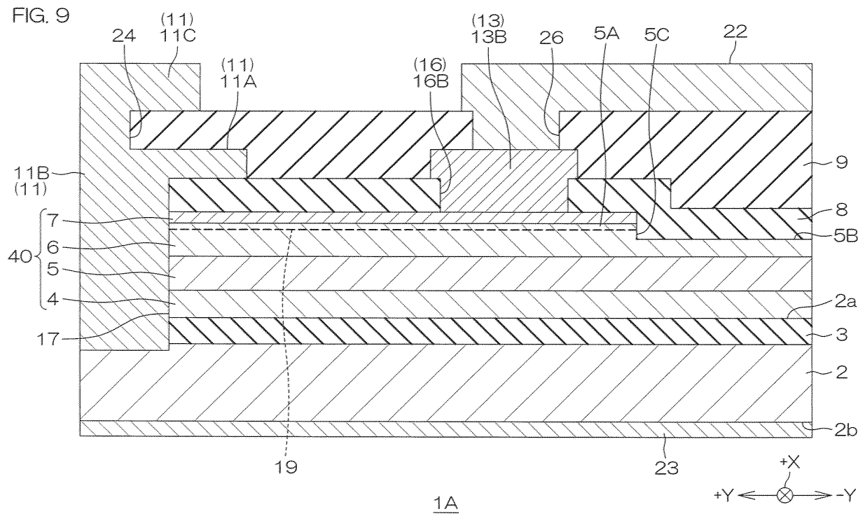

FIG. 7 is a plan view for describing the arrangement of a nitride semiconductor device according to a second preferred embodiment of the present disclosure. FIG. 8 is a sectional view taken along line VIII-VIII of FIG. 7. FIG. 9 is a sectional view taken along line IX-IX of FIG. 7. Here, an enlarged plan view of a principal portion of FIG. 7 is the same as the enlarged plan view of FIG. 2 and therefore, FIG. 2 is invoked as the enlarged plan view of the principal portion of FIG. 7.

In FIG. 7, FIG. 8, and FIG. 9, portions corresponding to respective portions in FIG. 1, FIG. 3, and FIG. 4 described above are provided with the same reference symbols as in FIG. 1, FIG. 3, and FIG. 4.

Referring to FIG. 2, FIG. 7, FIG. 8, and FIG. 9, a nitride semiconductor device 1A according to the second preferred embodiment differs from the nitride semiconductor device 1 according to the first preferred embodiment in that the semi-insulating SiC layer 3 is formed in an entirety of a surface layer portion of the conductive SiC substrate 2. Also, with the nitride semiconductor device 1A according to the second preferred embodiment, the back contact holes 17 and the plug portions 11B of the source electrodes 11 that are embedded in the back contact holes 17 differ from the back contact holes 17 and the plug portions 11B in the first preferred embodiment.

With the nitride semiconductor device 1A according to the second preferred embodiment, the back contact holes 17 penetrate continuously through the passivation film 8, the nitride epitaxial layer 40, and the semi-insulating SiC layer 3 from the front surface of the passivation film 8 and extend to an intermediate thickness of the conductive SiC substrate 2. Lower end portions of the plug portions 11B of the source electrodes 11 penetrate through the semi-insulating SiC layer 3 and reach an interior of the conductive SiC substrate 2.

In the second preferred embodiment, since the semi-insulating SiC layer 3 is formed in the entirety of the surface layer portion of the conductive SiC substrate 2, the parasitic capacitance can be reduced further in comparison to the first preferred embodiment. Although when the conductive SiC substrate 2 is used, the film thickness of the nitride epitaxial layer 40 needs to be made large to reduce the parasitic capacitance, with the second preferred embodiment, it is made possible to make the film thickness of the nitride epitaxial layer 40 small. The suppression of warping of the conductive SiC substrate 2 and internal cracks in the nitride epitaxial layer 40 and the reduction of parasitic capacitance are thereby enabled.

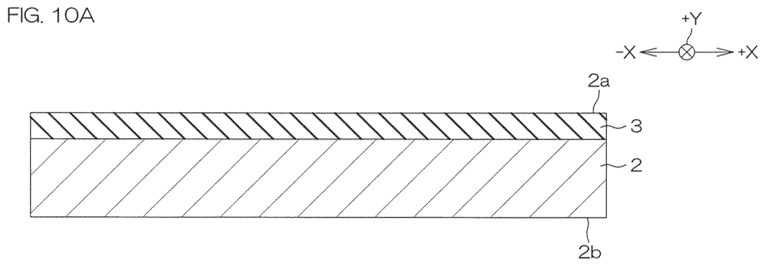

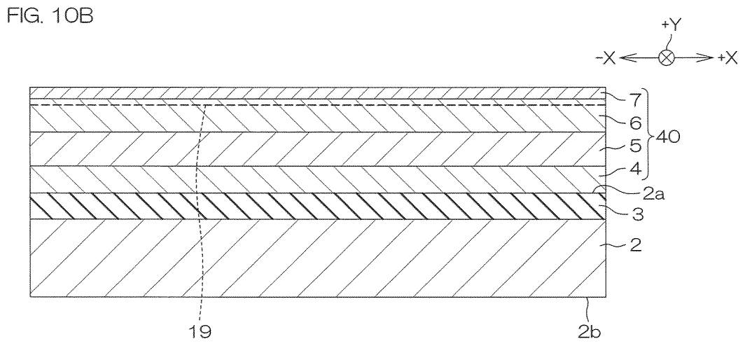

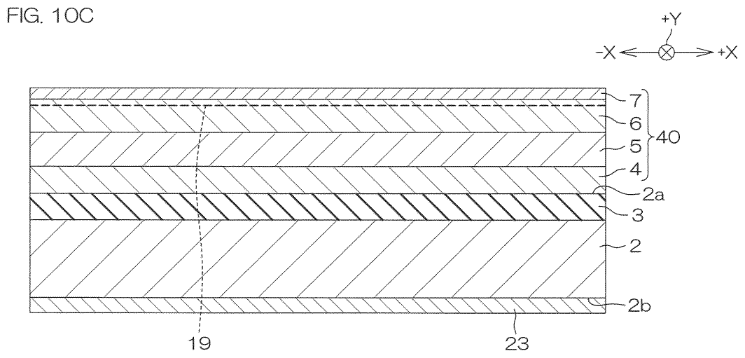

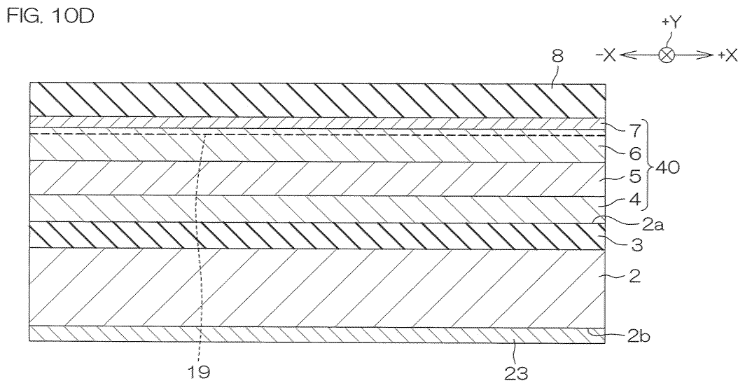

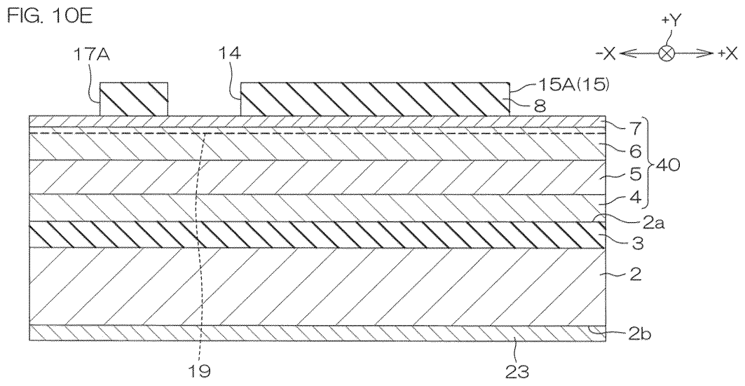

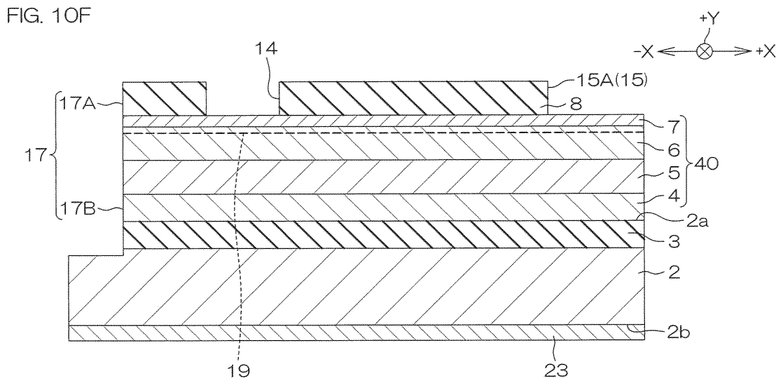

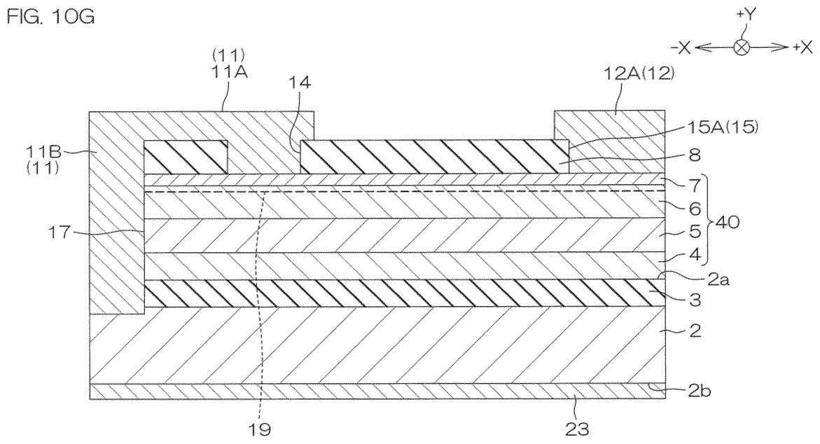

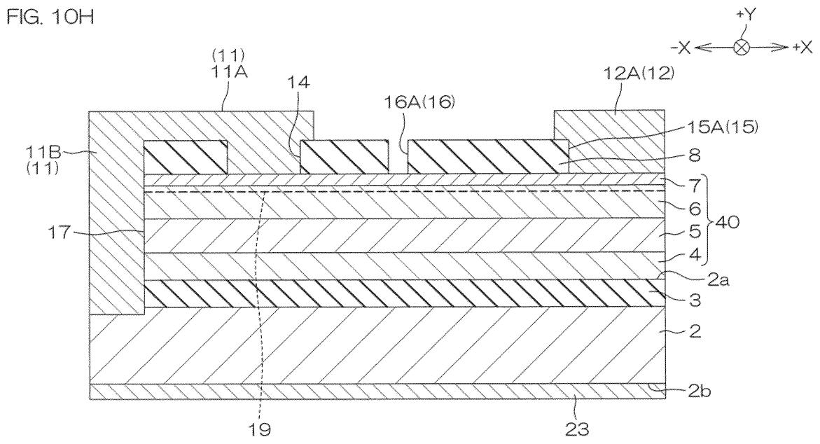

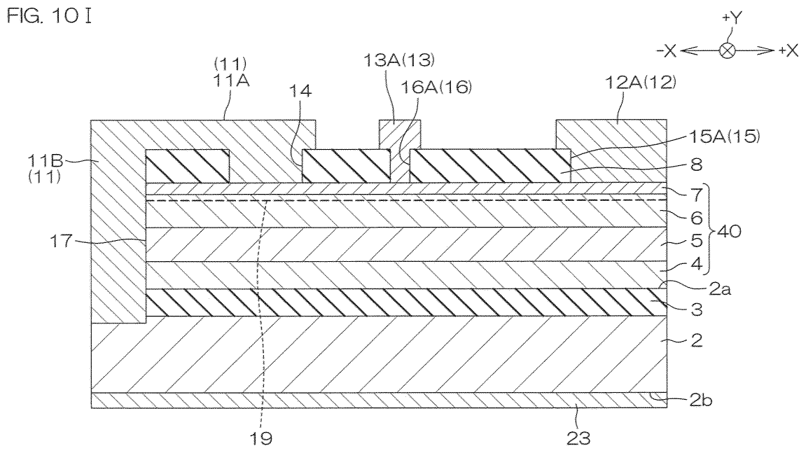

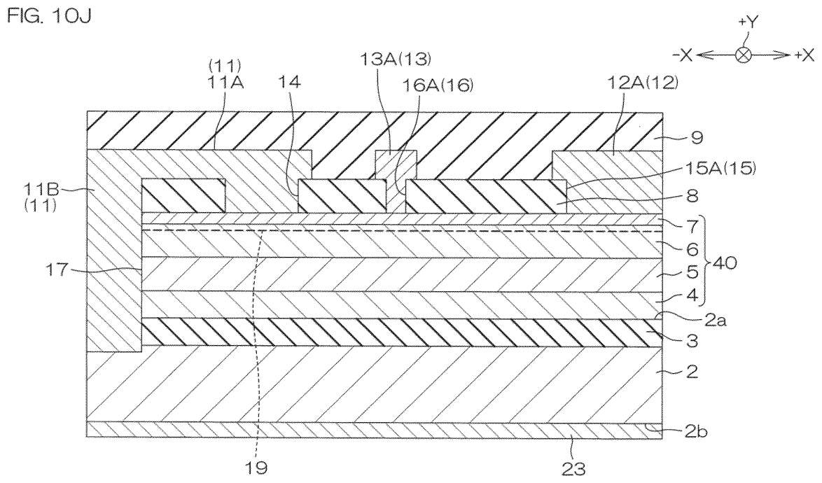

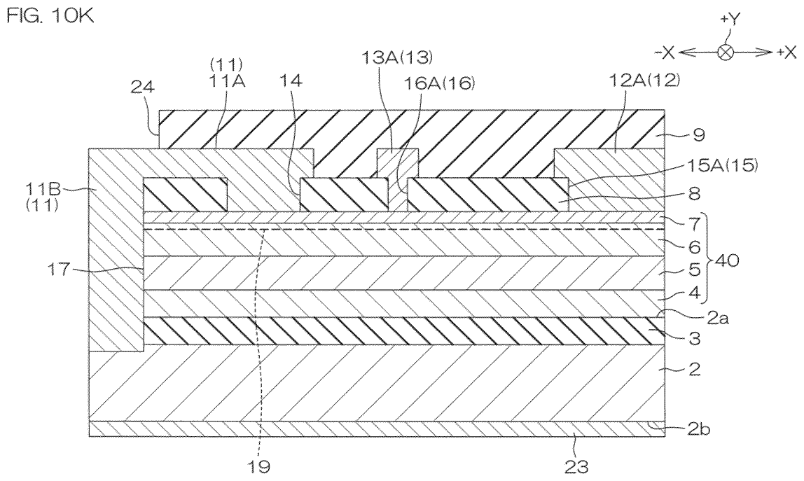

FIG. 10A to FIG. 10K are illustrative sectional views sequentially showing a manufacturing process of the nitride semiconductor device 1A shown in FIG. 7 to FIG. 9 and are sectional views corresponding to the section plane of FIG. 8.

First, as shown in FIG. 10A, the semi-insulating SiC layer 3 is formed in the entirety of the surface layer portion of the conductive SiC substrate 2 at the first surface 2a side. The semi-insulating SiC layer 3 is constituted of the plurality of first semi-insulating SiC layers 31 and the plurality of second semi-insulating SiC layers 32.

Next, as shown in FIG. 10B, the buffer layer 4 is epitaxially grown, for example, by an MOCVD method on the semi-insulating SiC layer 3 such as to cover the semi-insulating SiC layer 3. Further, the semi-insulating nitride layer 5, the first nitride semiconductor layer (electron transit layer) 6, and the second nitride semiconductor layer (electron supply layer) 7 are epitaxially grown successively on the buffer layer 4. The nitride epitaxial layer 40 constituted of the buffer layer 4, the semi-insulating nitride layer 5, the first nitride semiconductor layer 6, and the second nitride semiconductor layer 7 is thereby formed on the semi-insulating SiC layer 3.

Next, as shown in FIG. 10C, the source pad 23 is formed on the second surface 2b of the conductive SiC substrate 2, for example, by a sputtering method. The source pad 23 is constituted, for example, of Ni.

Next, a resist film (not shown) that covers a region directly above a planned formation region of the high step portion 5A of the front surface of the first nitride semiconductor layer 6 is formed on the second nitride semiconductor layer 7. By dry etching using the resist film as a mask, a peripheral edge portion of the second nitride semiconductor layer 7 is removed and a peripheral edge portion of the first nitride semiconductor layer 6 is removed down to an intermediate thickness. Also, the plurality of inactive region penetrating holes are formed in the second nitride semiconductor layer 7 and the plurality of inactive region recess portions that are in communication with the penetrating holes are formed in the first nitride semiconductor layer 6. The front surface of the first nitride semiconductor layer 6 is thereby made to be arranged from the high step portion 5A, the first low step portion 5B, the first connecting portion 5C connecting the high step portion 5A and the first low step portion 5B, the second low portions (not shown), and the second connecting portions connecting the high step portion 5A and the second low step portions. As the etching gas, for example, a chlorine-based gas such as Cl₂, BCl₃, SiCl₄, etc., is used.

The active region 110 in which the two-dimensional electron gas 19 can form and the inactive region 120 (121, 122) in which the two-dimensional electron gas 19 is not formed are thereby formed.

Here, the etching may be performed until an etching bottom surface reaches an upper surface of the semi-insulating nitride layer 5 or may be performed until it reaches an intermediate thickness of the semi-insulating nitride layer 5. Also, the etching may be performed until the etching bottom surface reaches an upper surface of the buffer layer 4 or may be performed until it reaches an intermediate thickness of the buffer layer 4.

Next, as shown in FIG. 10D, the passivation film 8 is formed by a plasma CVD method, LPCVD method, MOCVD method, sputtering method, etc., such as to cover exposed surfaces of the first nitride semiconductor layer 6 and exposed surfaces of the second nitride semiconductor layer 7.

Next, as shown in FIG. 10E, a resist film (not shown) is formed on the passivation film 8 at a region excluding regions in which the back contact holes 17, the source contact holes 14, and the drain contact hole 15 are to be formed. By the passivation film 8 being, for example, dry etched via the resist film, the portions 17A of the back contact holes 17, the source contact holes 14, and the drain contact hole 15 are formed in the passivation film 8. Thereafter, the resist film is removed.

The portions 17A of the back contact holes 17, the source contact holes 14, and the drain contact hole 15 penetrate through the passivation film 8 and reach the second nitride semiconductor layer 7. The widths of the source contact holes 14 and the drain contact hole 15 are approximately 3 μm to 5 μm. As the etching gas, for example, CF₄ gas is used. Also, SF₆ gas, CHF₃ gas, etc., may be used in place of CF₄ gas.

Next, as shown in FIG. 10F, a resist film (not shown) is formed on the passivation film 8 at a region excluding regions in which the back contact holes 17 are to be formed. Portions of the nitride epitaxial layer 40, the semi-insulating SiC layer 3, and the conductive SiC substrate 2 are etched, for example, by dry etching via the resist film.

Thereby, the holes 17B that penetrate through the nitride epitaxial layer 40 and the semi-insulating SiC layer 3 and reach the conductive SiC substrate 2 interior, in other words, the remaining portions 17B of the back contact holes 17 are formed. The back contact holes 17 each constituted of the portion 17A and the remaining portion 17B are thereby obtained. As the etching gas, for example, BCl₃ gas is used. Also, Cl₂ gas, SiCl₄ gas, etc., may be used in place of BCl₃ gas. The semi-insulating SiC layer 3 and the SiC substrate 2 may be etched using SF₆ gas. Thereafter, the resist film is removed.

Next, as shown in FIG. 10G, the source main electrode portions 11A and the plug portions 11B of the source electrodes 11 and the drain electrode 12 are formed, for example, by an Au plating method.

Next, as shown in FIG. 10H, a resist film (not shown) is formed on the passivation film 8 at a region excluding a region in which the gate contact hole 16 is to be formed. By the passivation film 8 being, for example, dry etched via the resist film, the gate contact hole 16 (16A, 16B) is formed in the passivation film 8. As the etching gas, for example, CF₄ gas is used. Also, SF₆ gas, CHF₃ gas, etc., may be used in place of CF₄ gas. Thereafter, the resist film is removed.

Next, as shown in FIG. 10I, the gate electrode 13 is formed, for example, by a lift-off method. Specifically, a resist film (not shown) is formed on the passivation film 8 at a region excluding a region in which the gate electrode 13 is to be formed. After an Ni/Au laminated film is vapor-deposited using the resist film as a mask, the resist film is removed.

Next, as shown in FIG. 10J, the interlayer insulating film 9 is formed, for example, by a CVD method or a sputtering method on the passivation film 8 such as to cover the source main electrode portions 11A, the drain electrode 12, and the gate electrode 13.

Next, as shown in FIG. 10K, a resist film (not shown) is formed on the interlayer insulating film 9 at a region excluding regions in which the source via holes 24, the drain via hole 25, and the gate via hole 26 are to be formed. By the interlayer insulating film 9 being, for example, dry etched via the resist film, the source via holes 24, the drain via hole 25, and the gate via hole 26 are formed in the interlayer insulating film 9. As the etching gas, for example, CF₄ gas is used. Also, SF₆ gas, CHF₃ gas, etc., may be used in place of CF₄ gas. Thereafter, the resist film is removed.

Lastly, the extension portions 11C of the source electrodes 11, the drain pad 21, and the gate pad 22 are formed, for example, by an Au plating method. The nitride semiconductor device 1A shown in FIG. 7 to FIG. 9 is thereby obtained.

Although with the first and second preferred embodiments described above, the semi-insulating nitride layer 5 is formed on the buffer layer 4, the semi-insulating nitride layer 5 does not have to be formed.

Also, although with the first and second preferred embodiments described above, an example where the first nitride semiconductor layer (electron transit layer) 6 is constituted of a GaN layer and the second nitride semiconductor layer (electron supply layer) 7 is constituted of an AlGaN layer was described, the first nitride semiconductor layer 6 and the second nitride semiconductor layer 7 suffice to differ in bandgap (for example, in Al composition) and other combinations are also possible. For examples, as combinations of the first nitride semiconductor layer 6/second nitride semiconductor layer 7, GaN/AlN, AlGaN/AlN, etc., can be cited as examples.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

What is claimed is:

1. A nitride semiconductor device comprising:
a conductive SiC substrate that has a first surface and a second surface opposite thereto;
a semi-insulating SiC layer that is formed in at least a portion of a surface layer portion at the first surface side of the conductive SiC substrate; and
a nitride epitaxial layer that is formed on the conductive SiC substrate such as to cover the semi-insulating SiC layer.

2. The nitride semiconductor device according to claim 1, wherein the nitride epitaxial layer on the semi-insulating SiC layer is formed on a silicon plane of the semi-insulating SiC layer.

3. The nitride semiconductor device according to claim 1, wherein a film thickness of the nitride epitaxial layer is not more than 4 μm.

4. The nitride semiconductor device according to claim 1, wherein a film thickness of the nitride epitaxial layer is not more than 2.5 μm.

5. The nitride semiconductor device according to claim 1, comprising:
a source electrode, a drain electrode, and a gate electrode that are disposed on the nitride epitaxial layer;
an insulating film that is formed on the nitride epitaxial layer such as to cover the source electrode, the drain electrode, and the gate electrode;
a gate pad that is formed on the insulating film and is electrically connected to the gate electrode; and
a drain pad that is formed on the insulating film and is electrically connected to the train electrode.

6. The nitride semiconductor device according to claim 5, wherein the semi-insulating SiC layer includes a first semi-insulating SiC layer that is formed inside a region below the drain pad in plan view.

7. The nitride semiconductor device according to claim 5, wherein the semi-insulating SiC layer includes a second semi-insulating SiC layer that is formed inside a region below the gate pad in plan view.

8. The nitride semiconductor device according to claim 5, wherein the semi-insulating SiC layer includes a first semi-insulating SiC layer that is formed inside a region below the drain pad in plan view and a second semi-insulating SiC layer that is formed inside a region below the gate pad in plan view.

9. The nitride semiconductor device according to claim 6, wherein the nitride semiconductor device has, in plan view, an active region in which a two-dimensional electron gas can form inside the nitride epitaxial layer and an inactive region in which a two-dimensional electron gas is not formed inside the nitride epitaxial layer,
the drain pad has a first drain pad region that is disposed inside the inactive region in plan view, and
the first semi-insulating SiC layer includes a portion that is disposed inside a region below the first drain pad region.

10. The nitride semiconductor device according to claim 7, wherein the nitride semiconductor device has, in plan view, an active region in which a two-dimensional electron gas can form inside the nitride epitaxial layer and an inactive region in which a two-dimensional electron gas is not formed inside the nitride epitaxial layer,
the gate pad has a first gate pad region that is disposed inside the inactive region in plan view, and
the second semi-insulating SiC layer includes a portion that is disposed inside a region below the first gate pad region.

11. The nitride semiconductor device according to claim 5, comprising: a conductive member that penetrates through the nitride epitaxial layer and electrically connects the source electrode and the conductive SiC substrate.

12. The nitride semiconductor device according to claim 1, wherein the nitride epitaxial layer includes
a first nitride semiconductor layer that constitutes an electron transit layer and
a second nitride semiconductor layer that is formed on the first nitride semiconductor layer, constitutes an electron supply layer, and is higher in bandgap than the first nitride semiconductor layer.

13. The nitride semiconductor device according to claim 12, comprising: a semi-insulating nitride layer that is disposed between the conductive SiC substrate and the first nitride semiconductor layer and with which an acceptor concentration is higher than a donor concentration.

14. The nitride semiconductor device according to claim 13, comprising: a buffer layer that is disposed between the conductive SiC substrate and the semi-insulating nitride layer and is constituted of a nitride semiconductor.

15. The nitride semiconductor device according to claim 12, wherein the first nitride semiconductor layer is constituted of a GaN layer and the second nitride semiconductor layer is constituted of an AlGaN layer.

16. The nitride semiconductor device according to claim 13, wherein the first nitride semiconductor layer is constituted of a GaN layer, the second nitride semiconductor layer is constituted of an AlGaN layer, and the semi-insulating nitride layer is constituted of a GaN layer that contains carbon.

17. The nitride semiconductor device according to claim 14, wherein the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of a laminated film of an AlN layer that is formed on the first surface and an AlGaN layer that is laminated on the AlN layer, an AlN layer, or an AlGaN layer.

18. The nitride semiconductor device according to claim 1, wherein a resistivity of the semi-insulating SiC layer is not less than 1×10³Ω·cm.

19. A method for manufacturing a nitride semiconductor device comprising:
a step of forming a semi-insulating SiC layer in at least a portion of a surface layer portion at a first surface side of a conductive SiC substrate that has the first surface and a second surface opposite thereto; and
a step of forming a nitride epitaxial layer on the conductive SiC substrate such as to cover the semi-insulating SiC layer.
